(19) United States
(12) Patent Application Publication
(10) Pub. No.: US 2025/0006876 A1
(43) Pub. Date: Jan. 2, 2025

(54) LIGHT EMITTING DEVICE AND ELECTRONIC DEVICE

(71) Applicant: Sony Semiconductor Solutions Corporation, Kanagawa (JP)

(72) Inventor: Masaya Ogura, Kanagawa (JP)

(21) Appl. No.: 18/697,810

(22) PCT Filed: Nov. 25, 2022
(86) PCT No.: PCT/JP2022/043476

§ 371 Date: Apr. 2, 2024

(30) Foreign Application Priority Data
Nov. 26, 2021 (JP) 2021-192116

(51) Int. Cl. H01L 33/58; H01L 25/075; H01L 33/42; H01L 33/50; H01L 33/62

(52) U.S. Cl. CPC H01L 33/58; H01L 25/0753; H01L 33/42; H01L 33/505; H01L 33/62

(57) ABSTRACT

There is provided a light emitting device (10) including a plurality of pixels (20) arranged on a substrate, in which a pixel of the plurality of pixels includes a plurality of subpixels (100), at least one subpixel of the plurality of subpixels includes a plurality of light emitting elements (200), each light emitting element includes: a first electrode (202) provided on the substrate (300); a light emitting layer (204) that is laminated on the first electrode and emits light; a second electrode (206) that is laminated on the light emitting layer and transmits light from the light emitting layer; and a first protective film (208) that is laminated on the second electrode and transmits light from the light emitting layer, and a second protective film (210) constituting an interface for guiding the light immediately above the light emitting element is embedded between the light emitting elements adjacent.

### FIELD

The present disclosure relates to a light emitting device and an electronic device.

### BACKGROUND

In recent years, a display device (light emitting device) using an organic electroluminescence (EL) element as a light emitting element has been developed. The display device includes, for example, a plurality of pixels including a lower electrode, a light emitting layer laminated on the lower electrode, and an upper electrode laminated on the light emitting layer. Then, when a predetermined voltage is supplied to the lower electrode and the upper electrode, the light emitting layer sandwiched between the lower electrode and the upper electrode emits light.

### CITATION LIST

### Patent Literature

Patent Literature 1: JP 2014-235959 A

### SUMMARY

### Technical Problem

However, in a display device (light emitting device) having a plurality of pixels as described above, a deeper study has not been made on improvement in light extraction efficiency from the pixels.

Therefore, the present disclosure proposes a light emitting device and an electronic device capable of improving light extraction efficiency.

### Solution to Problem

According to the present disclosure, there is provided a light emitting device including a plurality of pixels arranged on a substrate. In the light emitting device, a pixel of the plurality of pixels includes a plurality of subpixels, at least one subpixel of the plurality of subpixels includes a plurality of light emitting elements, each light emitting element includes: a first electrode provided on the substrate; a light emitting layer that is laminated on the first electrode and emits light; a second electrode that is laminated on the light emitting layer and transmits light from the light emitting layer; and a first protective film that is laminated on the second electrode and transmits light from the light emitting layer, and a second protective film constituting an interface for guiding the light immediately above the light emitting element is embedded between the light emitting elements adjacent.

Furthermore, according to the present disclosure, there is provided an electronic device on which a light emitting device including a plurality of pixels arranged on a substrate is mounted. In the light emitting device, a pixel of the plurality of pixels includes a plurality of subpixels, at least one subpixel of the plurality of subpixels includes a plurality of light emitting elements, each light emitting element includes: a first electrode provided on the substrate; a light emitting layer that is laminated on the first electrode and emits light; a second electrode that is laminated on the light emitting layer and transmits light from the light emitting layer; and a first protective film that is laminated on the second electrode and transmits light from the light emitting layer, and a second protective film constituting an interface for guiding the light immediately above the light emitting element is embedded between the light emitting elements adjacent.

### BRIEF DESCRIPTION OF DRAWINGS

FIG. 1 is a schematic diagram illustrating an example of an overall configuration of a light emitting device 10 according to an embodiment of the present disclosure.

FIG. 2 is a schematic circuit diagram for explaining a connection relationship in a subpixel 100 in an m-th row and an n-th column.

FIG. 3 is a cross-sectional view for explaining an example of a configuration of a pixel according to a comparative example.

FIG. 4 is a cross-sectional view for explaining an example of a configuration of a pixel according to the first embodiment of the present disclosure.

FIG. 5 is a conceptual diagram for explaining a concept of the first embodiment of the present disclosure.

FIG. 6 is an explanatory diagram illustrating a simulation result regarding the light emitting element according to the first embodiment of the present disclosure.

FIG. 7 is a plan view for explaining a concept of the first embodiment of the present disclosure.

FIG. 8 is a cross-sectional view for explaining an example of a configuration of a pixel according to a modification of the first embodiment of the present disclosure.

FIG. 9 is an explanatory diagram for explaining the method for manufacturing the pixel according to the first embodiment of the present disclosure.

FIG. 10 is a plan view for explaining an example of a configuration of a pixel according to the second embodiment of the present disclosure.

FIG. 11A is a plan view (part 1) for explaining an example of a configuration of a pixel according to a modification of the second embodiment of the present disclosure.

FIG. 11B is a plan view (part 2) for explaining an example of a configuration of a pixel according to a modification of the second embodiment of the present disclosure.

FIG. 11C is a plan view (part 3) for explaining an example of a configuration of a pixel according to a modification of the second embodiment of the present disclosure.

FIG. 11D is a plan view (part 4) for explaining an example of a configuration of a pixel according to a modification of the second embodiment of the present disclosure.

FIG. 11E is a plan view (part 5) for explaining an example of a configuration of a pixel according to a modification of the second embodiment of the present disclosure.

FIG. 11F is a plan view (part 6) for explaining an example of a configuration of a pixel according to a modification of the second embodiment of the present disclosure.

FIG. 11G is a plan view (part 7) for explaining an example of a configuration of a pixel according to a modification of the second embodiment of the present disclosure.

FIG. 11H is a plan view (part 8) for explaining an example of a configuration of a pixel according to a modification of the second embodiment of the present disclosure.

FIG. 12 is a cross-sectional view for explaining an example of a configuration of a subpixel according to a comparative example.

FIG. 13 is a cross-sectional view for explaining an example of a configuration of a subpixel according to the third embodiment of the present disclosure.

FIG. 14 is a cross-sectional view for explaining an example of a configuration of a pixel according to the fourth embodiment of the present disclosure.

FIG. 15 is a cross-sectional view for explaining an example of a configuration of a light emitting element according to the fifth embodiment of the present disclosure.

FIG. 16A is a cross-sectional view (part 1) for explaining an example of a configuration of a light emitting element according to a modification of the fifth embodiment of the present disclosure.

FIG. 16B is a cross-sectional view (part 2) for explaining an example of a configuration of a light emitting element according to a modification of the fifth embodiment of the present disclosure.

FIG. 16C is a cross-sectional view (part 3) for explaining an example of a configuration of a light emitting element according to a modification of the fifth embodiment of the present disclosure.

FIG. 17 is a cross-sectional view (part 1) for explaining an example of a configuration of a pixel according to the sixth embodiment of the present disclosure.

FIG. 18 is a cross-sectional view (part 2) for explaining an example of a configuration of a pixel according to the sixth embodiment of the present disclosure.

FIG. 19 is a cross-sectional view (part 3) for explaining an example of a configuration of a pixel according to the sixth embodiment of the present disclosure.

FIG. 20 is a plan view (part 1) for explaining an example of a configuration of a pixel according to the seventh embodiment of the present disclosure.

FIG. 21 is a plan view (part 2) for explaining an example of a configuration of a pixel according to the seventh embodiment of the present disclosure.

FIG. 22 is a plan view (part 3) for explaining an example of a configuration of a pixel according to the seventh embodiment of the present disclosure.

FIG. 23 is a plan view (part 4) for explaining an example of a configuration of a pixel according to the seventh embodiment of the present disclosure.

FIG. 24A is a conceptual diagram (part 1) for explaining a relationship among a normal line LN passing through the center of the light emitting unit, a normal line LN′ passing through the center of the lens member, and a normal line LN″ passing through the center of the wavelength selection unit.

FIG. 24B is a conceptual diagram (part 2) for explaining a relationship among a normal line LN passing through the center of the light emitting unit, a normal line LN′ passing through the center of the lens member, and a normal line LN″ passing through the center of the wavelength selection unit.

FIG. 24C is a conceptual diagram (part 3) for explaining a relationship among a normal line LN passing through the center of the light emitting unit, a normal line LN′ passing through the center of the lens member, and a normal line LN″ passing through the center of the wavelength selection unit.

FIG. 24D is a conceptual diagram (part 4) for explaining a relationship among a normal line LN passing through the center of the light emitting unit, a normal line LN′ passing through the center of the lens member, and a normal line LN″ passing through the center of the wavelength selection unit.

FIG. 24E is a conceptual diagram (part 5) for explaining a relationship among a normal line LN passing through the center of the light emitting unit, a normal line LN′ passing through the center of the lens member, and a normal line LN″ passing through the center of the wavelength selection unit.

FIG. 24F is a conceptual diagram (part 6) for explaining a relationship among a normal line LN passing through the center of the light emitting unit, a normal line LN′ passing through the center of the lens member, and a normal line LN″ passing through the center of the wavelength selection unit.

FIG. 24G is a conceptual diagram (part 7) for explaining a relationship among a normal line LN passing through the center of the light emitting unit, a normal line LN′ passing through the center of the lens member, and a normal line LN″ passing through the center of the wavelength selection unit.

FIG. 25 is a schematic cross-sectional view for explaining a first example of the resonator structure.

FIG. 26 is a schematic cross-sectional view for explaining a second example of the resonator structure.

FIG. 27 is a schematic cross-sectional view for explaining a third example of the resonator structure.

FIG. 28 is a schematic cross-sectional view for explaining a fourth example of the resonator structure.

FIG. 29 is a schematic cross-sectional view for explaining a fifth example of the resonator structure.

FIG. 30 is a schematic cross-sectional view for explaining a sixth example of the resonator structure.

FIG. 31 is a schematic cross-sectional view for explaining a seventh example of the resonator structure.

FIG. 32A is a front view illustrating an example of an external appearance of a digital still camera.

FIG. 32B is a rear view illustrating an example of an external appearance of the digital still camera.

FIG. 33 is an external view of a head mounted display.

FIG. 34 is an external view of a see-through head mounted display.

FIG. 35 is an external view of a television apparatus.

FIG. 36 is an external view of a smartphone.

FIG. 37A is a diagram (part 1) illustrating an internal configuration of an automobile.

FIG. 37B is a diagram (part 2) illustrating an internal configuration of an automobile.

### DESCRIPTION OF EMBODIMENTS

Hereinafter, preferred embodiments of the present disclosure will be described in detail with reference to the accompanying drawings. Note that, in the present specification and the drawings, components having substantially the same functional configurations are denoted by the same reference signs, and redundant description is omitted. In addition, in the present specification and the drawings, a plurality of components having substantially the same or similar functional configuration may be distinguished by attaching different alphabets after the same reference sign. However, in a case where it is not particularly necessary to distinguish each of a plurality of components having substantially the same or similar functional configuration, only the same reference sign is attached.

The shape expressed in the following description means not only a mathematically or geometrically defined shape but also a similar shape including an allowable difference (error/distortion) in the operation of the light emitting device and the manufacturing process of the light emitting device. Furthermore, “identical” used for a specific shape in the following description does not mean only a case of mathematically or geometrically perfect agreement, but also a case of having an allowable difference (error/distortion) in the operation of the light emitting device and the manufacturing process of the light emitting device.

Furthermore, in the following description, “electrically connecting” means connecting a plurality of elements directly or indirectly via other elements.

Furthermore, in the following description, “sharing” means that one other element (for example, an on-chip lens or the like) is used together between elements different from each other (for example, a pixel or the like).

Note that the description will be given in the following order.
1. Overall Configuration of Light Emitting Device According to Embodiment of Present Disclosure
2. Background to Creation of Embodiments of Present Disclosure
2.1 Background
2.2 Outline of Embodiment of Present Disclosure
3. First Embodiment
3.1 Detailed Configuration
3.2 Modification
3.3 Manufacturing Method
4. Second Embodiment
4.1 Detailed Configuration
4.2 Modification
5. Third Embodiment
6. Fourth Embodiment
7. Fifth Embodiment
7.1 Detailed Configuration
7.2 Modification
8. Sixth Embodiment
9. Seventh Embodiment
10. Summary
11. Modification
11.1 Modification 1
11.2 Modification 2
12. Application Example
13. Supplement

### 1. Overall Configuration of Light Emitting Device According to Embodiment of Present Disclosure

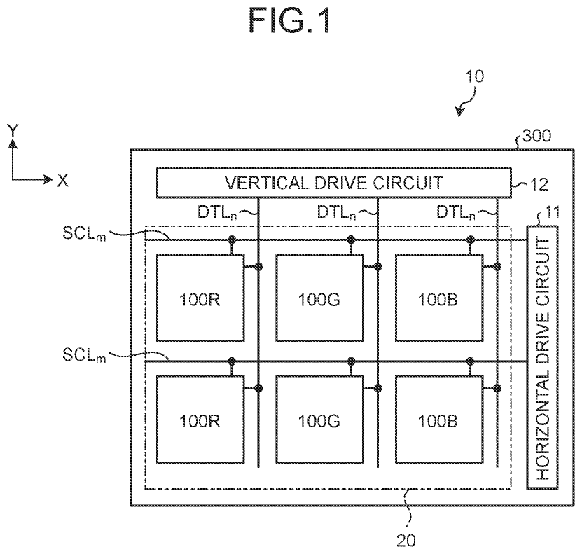

An example of an overall configuration of an organic electro luminescence (EL) light emitting device 10 (hereinafter, simply referred to as “light emitting device 10”) according to an embodiment of the present disclosure used as a display device or a lighting device will be described with reference to FIG. 1. FIG. 1 is a schematic diagram illustrating an example of an overall configuration of a light emitting device 10 according to an embodiment of the present disclosure.

The light emitting device 10 is, for example, a device in which light emitting elements such as an organic light emitting diode (OLED) or a micro-OLED are formed in an array. Such a light emitting device 10 can be applied to, as a display device, for example, a display device for virtual reality (VR), mixed reality (MR), or augmented reality (AR), an electronic view finder (EVF), a small projector, or the like.

The light emitting device 10 has a display region and a peripheral region provided on a peripheral edge of the display region. As illustrated in FIG. 1, a plurality of subpixels 100R, 100G, and 100B is arranged in a matrix in a display region of the light emitting device 10. The subpixel 100R may emit red light, the subpixel 100G may emit green light, and the subpixel 100B may emit blue light. Note that, in the following description, the subpixels 100R, 100G, and 100B are referred to as subpixels 100 unless otherwise distinguished.

Furthermore, in the present embodiment, one pixel (pixel) 20 is configured by, for example, combining three types of subpixels 100R, 100G, and 100B that emit different types of light. Note that, in the present embodiment, the number and arrangement of each of the three types of subpixels 100R, 100G, and 100B included in one pixel 20 are not particularly limited. Furthermore, in the present embodiment, one pixel 20 is not limited to being configured by the plurality of subpixels 100 that emits different light as described above, and may be configured by the plurality of subpixels 100 that emits the same color light. Furthermore, the pixel 20 is also the minimum unit (pixel) controlled at the time of light emission control of the light emitting device 10, and includes a plurality of subpixels 100 treated as one unit at the time of control. Furthermore, in the present embodiment, the light emitting device 10 includes a plurality of pixels 20 arranged in a matrix on a substrate.

In addition, as illustrated in FIG. 1, a horizontal drive circuit 11 and a vertical drive circuit 12 are provided in a peripheral region of the light emitting device 10.

The horizontal drive circuit 11 can scan each subpixel 100 in units of rows (in FIG. 1, a direction extending along the X direction is referred to as a row direction) when writing a signal to each subpixel, and sequentially supply a scanning signal to each scanning line SCLₘ. The horizontal drive circuit 11 can include, for example, a shift register or the like that sequentially shifts (transfers) a start pulse in synchronization with an input clock pulse.

Furthermore, the vertical drive circuit 12 can supply a signal voltage of a signal corresponding to luminance information supplied from a signal supply source (not illustrated) to the subpixels 100 selected in units of columns (in FIG. 1, a direction extending along the Y direction is referred to as a column direction) via the signal line DTLₙ.

Note that, in the embodiment of the present disclosure, the configuration of the light emitting device 10 is not limited to the configuration illustrated in FIG. 1. That is, the configuration illustrated in FIG. 1 is merely an example, and the light emitting device 10 according to the embodiment of the present disclosure can take various configurations.

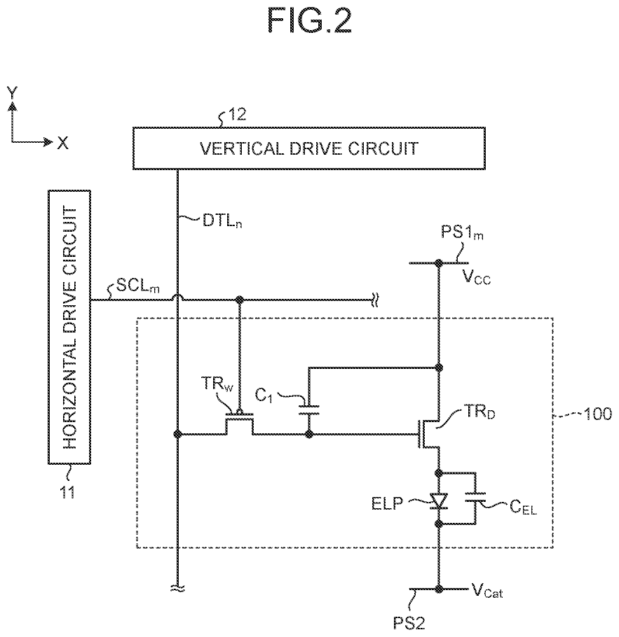

Next, a circuit configuration of the subpixel 100 in the m-th row and the n-th column will be described with reference to FIG. 2. FIG. 2 is a schematic circuit diagram for explaining a connection relationship in the subpixel 100 in the m-th row and the n-th column.

In the light emitting device 10, as described above, the subpixels 100 including the light emitting elements ELP are arranged in a two-dimensional matrix in a state of being connected to the scanning line SCLₘ extending in the row direction (X direction in FIG. 1) and the signal line DTLₙ extending in the column direction (Y direction in FIG. 1).

Furthermore, as illustrated in FIG. 2, the light emitting device 10 includes a feeder line PS1ₘ that supplies a drive voltage to the subpixel 100, and a common feeder line PS2 that is commonly connected to all the subpixels 100. Then, a predetermined drive voltage V_{cc} or the like is supplied from a power supply unit (not illustrated) to the feeder line PS1ₘ, and a common voltage V_{cat} (for example, ground potential) is supplied to the common feeder line PS2.

Here, it is assumed that the number of scanning lines SCL and the number of feeder lines PS1 are each M. The subpixels 100 in the myth row (where m=1, 2 . . . , P) are connected to the m-th scanning line SCLₘ and the m-th feeder line PS1ₘ, and form one display element row. Note that, in FIG. 2, only the scanning line SCLₘ and the feeder line PS1ₘ are illustrated. In addition, the number of signal lines DTL is set to N. The subpixel 100 in the n-th column (where n=1, 2 . . . , N) is connected to the n-th signal line DTLₙ Note that, in FIG. 2, only the signal line DTLₙ is illustrated. Hereinafter, the subpixel 100 located in the m-th row and the n-th column may be referred to as a (n, m)-th subpixel 100.

Then, as described above, the light emitting device 10 is sequentially scanned row by row by the scanning signal from the horizontal drive circuit 11. Specifically, in the light emitting device 10, the M subpixels 100 arranged in the m-th row are simultaneously driven. In other words, in the M subpixels 100 arranged along the row direction, the light emission/non-light emission timing is controlled in units of rows to which they belong. For example, in a case where the display frame rate of the light emitting device 10 is FR (times/second), a scanning period per row (so-called horizontal scanning period) when the light emitting device 10 is sequentially scanned row by row is less than (1/FR)×(1/P) seconds.

Furthermore, as illustrated in FIG. 2, the subpixel 100 includes a light emitting element ELP and a drive circuit that drives the light emitting element ELP. The light emitting element ELP is made of an organic electroluminescence light emitting element. The drive circuit includes a write transistor TR_{W}, a drive transistor TR_{D}, and a capacitor C₁. When a current flows through the light emitting element ELP via the drive transistor TR_{D}, the light emitting element ELP can emit light. Each transistor includes, for example, a p-channel field effect transistor.

As illustrated in FIG. 2, in the subpixel 100, one source/drain region of the drive transistor TR_{D} is electrically connected to one end of the capacitor C₁ and the feeder line PS1ₘ, and the other source/drain region is electrically connected to one end (specifically, the anode electrode) of the light emitting element ELP. A gate electrode of the drive transistor TR_{D} is connected to the other source/drain region of the write transistor TR_{W}, and is electrically connected to the other end of the capacitor C₁.

Furthermore, as illustrated in FIG. 2, one source/drain region of the write transistor TR_{w} is electrically connected to the signal line DTL_{D}, and the gate electrode of the write transistor TR_{w} is electrically connected to the scanning line SCLₘ.

In addition, as illustrated in FIG. 2, the other end (specifically, the cathode electrode) of the light emitting element ELP is electrically connected to the common feeder line PS2. Further, a predetermined cathode voltage V_{cat} is supplied to the common feeder line PS2. Note that, in FIG. 2, the capacitance of the light emitting element ELP is represented by a reference sign C_{EL}.

An outline of driving of the subpixel 100 will be described. When the write transistor TR_{w} is brought into a conductive state by the scanning signal from the horizontal drive circuit 11 in a state where the voltage corresponding to the luminance of the image to be displayed on the signal line DTLₙ is supplied from the vertical drive circuit 12, the voltage corresponding to the luminance is written in the capacitor C₁. After the write transistor TR_{w} is brought into the non-conductive state, a current flows through the drive transistor TR_{D} according to the voltage held in the capacitor C₁, whereby the light emitting element ELP emits light.

Note that, in the embodiment of the present disclosure, the configuration of the drive circuit that controls the light emission of the light emitting element ELP is not limited to the configuration illustrated in FIG. 2. Therefore, the configuration illustrated in FIG. 2 is merely an example, and the light emitting device 10 according to the embodiment of the present disclosure can take various configurations.

### 2. Background to Creation of Embodiments of Present Disclosure

### <2.1 Background>

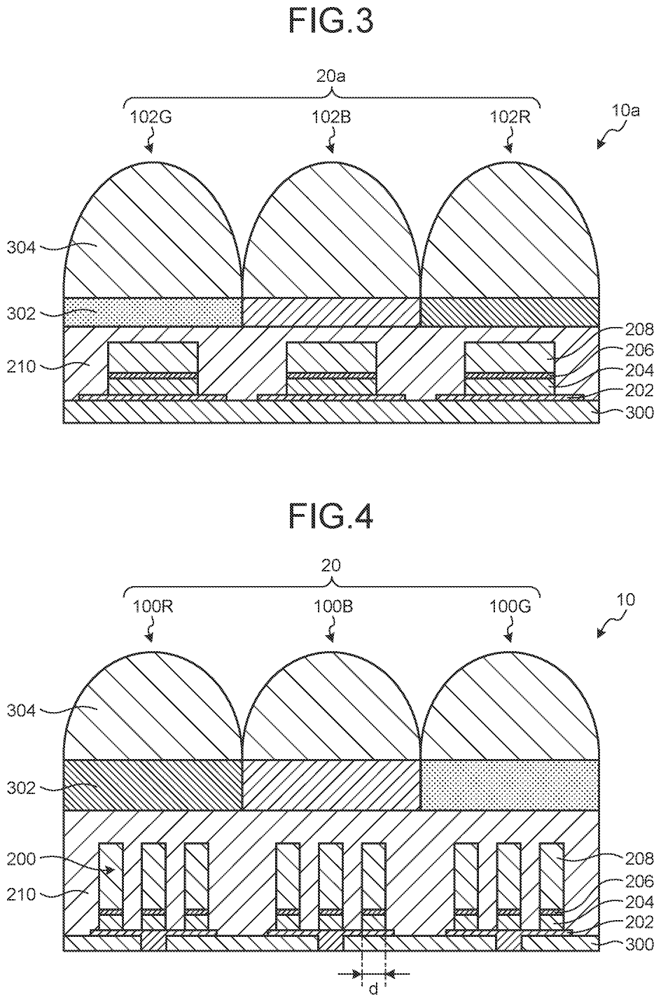

Next, before describing the embodiments of the present disclosure, the background leading to the creation of the embodiments of the present disclosure by the present inventor will be described with reference to FIG. 3. FIG. 3 is a cross-sectional view for explaining an example of a configuration of a pixel 20a according to a comparative example. Note that, here, the comparative example means the pixel 20a that has been repeatedly examined by the present inventor before the embodiments of the present disclosure are made.

As described above, a light emitting device 10a according to the comparative example includes a plurality of pixels 20a, and for example, the pixel 20a is configured by a combination of three types of subpixels 102R, 102G, and 102B as illustrated in FIG. 3. Here, it is assumed that the subpixel 102R can emit red light, the subpixel 102G can emit green light, and the subpixel 102B can emit blue light. Note that, in the comparative example, the number and arrangement of each of the three types of subpixels 102R, 102G, and 102B included in one pixel 20a are not limited.

Furthermore, as illustrated in FIG. 3, each subpixel 102 includes an anode electrode (first electrode) 202 provided on a substrate 300, a light emitting layer 204 laminated on the anode electrode 202, a cathode electrode (second electrode) 206 laminated on the light emitting layer 204 and transmitting light from the light emitting layer 204, and a protective film (first protective film) 208 laminated on the cathode electrode 206 and transmitting light from the light emitting layer 204.

Then, as illustrated in FIG. 3, the subpixel 102 is covered with a protective film (second protective film) 210, and a color filter 302 and an on-chip lens 304 are provided on the protective film 210 for each subpixel 102.

In the pixel 20a according to such a comparative example, when a predetermined voltage is supplied to the anode electrode 202 and the cathode electrode 206, the light emitting layer 204 sandwiched between the anode electrode 202 and the cathode electrode 206 emits light. Specifically, in the comparative example, light is emitted from the light emitting layer 204 along the direction from the anode electrode 202 toward the cathode electrode 206. In other words, the light emitting device 10a according to the comparative example is a top emission type light emitting device.

The present inventor has intensively studied to further improve the light extraction efficiency from each subpixel 102 in such a pixel 20a. In the subpixel 102 according to the comparative example, since the radiation angle of the light from the light emitting layer 204 in FIG. 3 is large and the light is widely diffused, there is a limit in improving the light extraction efficiency of the light emitting device 10 upward in the drawing. Therefore, the present inventor of the present disclosure has realized that the light extraction efficiency of the light emitting device 10 can be further improved if the spread of the light radiated upward from each subpixel 102 can be narrowed (in other words, the radiation angle is reduced), and has created the embodiments of the present disclosure described below.

### <2.2 Outline of Embodiment of Present Disclosure>

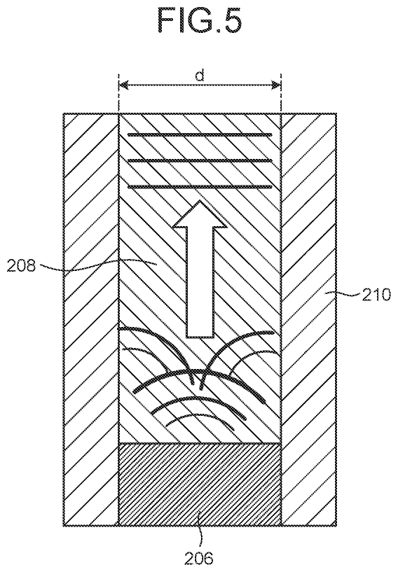

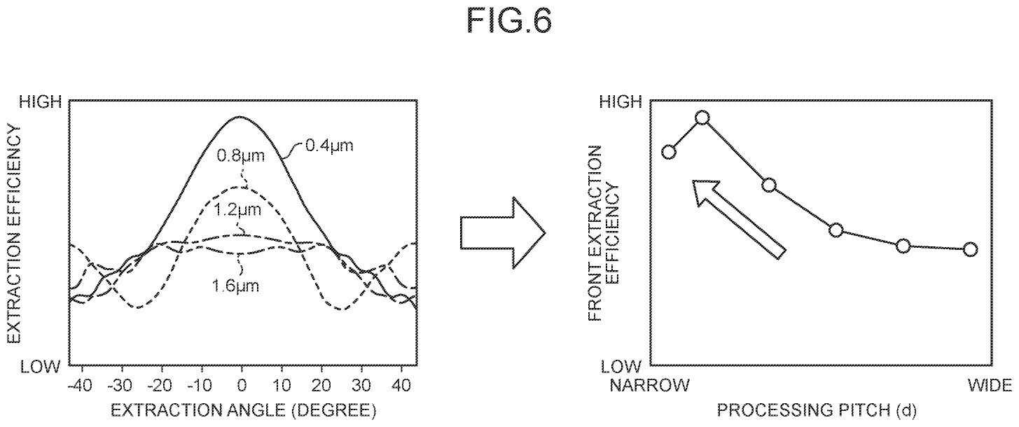

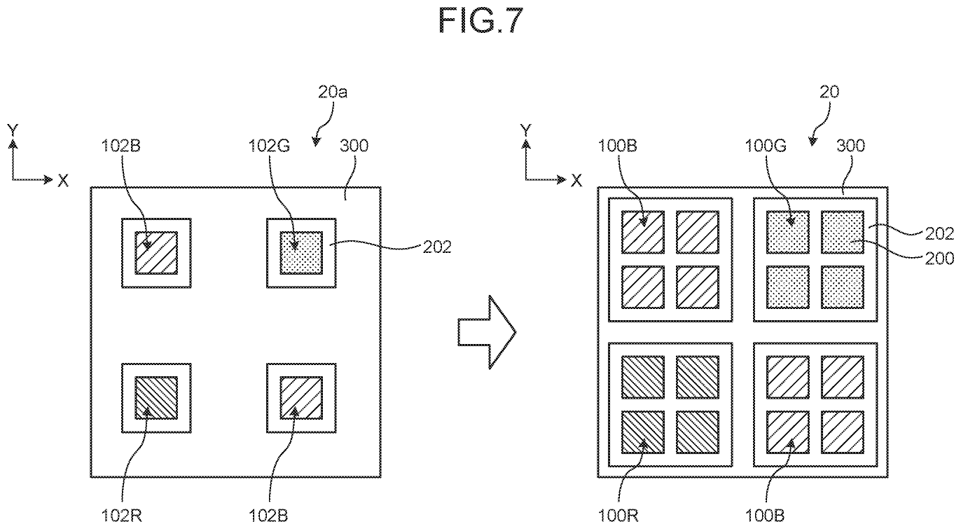

Next, an outline of an embodiment of the present disclosure created by the present inventor will be described with reference to FIGS. 4 to 7. FIG. 4 is a cross-sectional view for explaining an example of the configuration of the pixel 20 according to the first embodiment of the present disclosure, and specifically, is a cross-sectional view of the pixel 20 cut in a direction perpendicular to the plane of the substrate 300. Furthermore, FIG. 5 is a conceptual diagram for explaining a concept of the first embodiment of the present disclosure, and FIG. 6 is an explanatory diagram illustrating a simulation result regarding the light emitting element 200 according to the first embodiment of the present disclosure. Furthermore, FIG. 7 is a plan view for explaining the concept of the first embodiment of the present disclosure. Specifically, the left side of FIG. 7 illustrates a case where the pixel 20a according to the comparative example is cut parallel to the plane of the substrate 300 at the height of the light emitting layer 204, and the right side of FIG. 7 illustrates a case where the pixel 20 according to the present embodiment is cut parallel to the plane of the substrate 300 at the height of the light emitting layer 204.

First, as illustrated in FIG. 4, in the first embodiment of the present disclosure created by the present inventor, similarly to the comparative example, the pixel 20 is configured by combining three types of subpixels 100R, 100G, and 100B that emit light of different colors. Here, it is assumed that the subpixel 100R can emit red light, the subpixel 100G can emit green light, and the subpixel 100B can emit blue light. Note that, also in the present embodiment, the number and arrangement of each of the three types of subpixels 100R, 100G, and 100B included in one pixel 20 are not limited. However, in the present embodiment, unlike the comparative example, each subpixel 100 includes a plurality of light emitting elements 200 that emits the same color light. In other words, in the present embodiment, the subpixel 100 is divided into a plurality of light emitting elements 200.

Further, as illustrated in FIG. 4, each light emitting element 200 has an anode electrode (first electrode) 202 provided on the substrate 300, a light emitting layer 204 laminated on the anode electrode 202, a cathode electrode (second electrode) 206 laminated on the light emitting layer 204 and transmitting light from the light emitting layer 204, and a protective film (first protective film) 208 laminated on the cathode electrode 206 and transmitting light from the light emitting layer 204, similarly to the comparative example.

Then, in the present embodiment, as illustrated in FIG. 4, the space between the light emitting elements 200 is filled with a protective film (second protective film) 210. Furthermore, in the present embodiment, similarly to the comparative example, a color filter 302 and an on-chip lens 304 are provided for each subpixel 100.

In the present embodiment created by the present inventor of the present disclosure, by further finely dividing the subpixel 100 so as to include the plurality of light emitting elements 200, the light extraction efficiency of the light emitting device 10 can be improved. Specifically, as can be seen from FIG. 5 schematically illustrating the cathode electrode and the protective film 208 of the light emitting element 200 according to the present embodiment, the width d of the light emitting element 200 is narrowed in the present embodiment. By thus narrowing the width d of the light emitting element 200, the light from the light emitting layer 204 is diffracted many times at the boundary between the protective film 208 and the protective film 210, so that the light is confined in the protective film 208 and interferes therewith. Therefore, more light from the light emitting layer 204 is emitted upward in FIG. 5. That is, by narrowing the width d of the light emitting element 200, the protective film 208 functions like a waveguide, and the light from the light emitting layer 204 can be guided upward while being suppressed from spreading. As a result, in the present embodiment, it is possible to improve the upward light extraction efficiency of the light emitting device 10.

More specifically, FIG. 6 illustrates a simulation result of the change in the degree of spread of light with respect to the width d of the light emitting element 200 by the present inventor. Specifically, FIG. 6 illustrates a graph illustrating the relationship between the width d of the light emitting element 200 and the light extraction angle (degree of spread) and the light extraction efficiency (light intensity), and a graph illustrating the relationship between the width d (processing pitch) of the light emitting element 200 and the light extraction efficiency in front of the light emitting element 200, based on the simulation results. As can be seen from FIG. 6, by narrowing the width d of the light emitting element 200, the spread of light from the light emitting layer 204 is suppressed, and the light extraction efficiency of the light emitting device 10 in front of the light emitting element 200 can be improved.

That is, in order to improve light extraction of the light emitting device 10, the width d of the light emitting element 200 is narrowed. However, for example, in a case where the width of the subpixel 102 is narrowed in the subpixel 102 having the configuration of the comparative example as illustrated on the left side of FIG. 7, the aperture ratio conversely decreases, and the light from the light emitting device 10a decreases. In other words, there is a trade-off relationship between the improvement of the light extraction efficiency and the improvement of the aperture ratio by narrowing the width of the subpixel 102. Note that the aperture ratio is a ratio of the area of the light emitting layer 204 to the area of the substrate 300 when viewed from above the substrate 300.

Therefore, as illustrated on the right side of FIG. 7, the present inventor provides a plurality of light emitting elements 200 having a narrow width d in the subpixel 100, thereby improving light extraction efficiency without reducing the aperture ratio.

That is, according to the embodiment of the present disclosure created by the present inventor, the light extraction efficiency can be improved without reducing the aperture ratio. Hereinafter, details of embodiments of the present disclosure created by the present inventors will be sequentially described.

### 3. First Embodiment

### <3.1 Detailed Configuration>

First, a detailed configuration of the subpixel 100 in the first embodiment of the present disclosure will be described with reference to FIGS. 4 and 7.

First, as illustrated in FIG. 4, in the first embodiment of the present disclosure, as described above, the pixel 20 is configured by combining three types of subpixels 100R, 100G, and 100B that emit light of different colors. Here, it is assumed that the subpixel 100R can emit red light (for example, visible light having a wavelength of about 640 nm to 770 nm), the subpixel 100G can emit green light (for example, visible light having a wavelength of about 490 nm to 550 nm), and the subpixel 100B can emit blue light (for example, visible light having a wavelength of about 430 nm to 490 nm). Note that, in the present embodiment, the number and arrangement of each of the three types of subpixels 100R, 100G, and 100B included in one pixel 20 are not limited. Furthermore, in the present embodiment, the pixel 20 may include a subpixel 100 that emits light other than red light, blue light, and green light.

Furthermore, in the present embodiment, each subpixel 100 includes a plurality of light emitting elements 200 that emits light of the same color. Note that, in the present embodiment, each subpixel 100 only needs to include the plurality of light emitting elements 200, and is not limited to including the plurality of light emitting elements 200 that emits light of the same color. In the present embodiment, as illustrated on the right side of FIG. 7, the light emitting element 200 preferably has a rectangular shape when viewed from above the substrate 300 (in plan view), and the length of one side of the light emitting element 200 (that is, the width d) is preferably about 400 nm to 800 nm. Note that, in the present embodiment, the shape of the light emitting element 200 in plan view is not limited to a rectangular shape, and may be, for example, a polygonal shape, a circular shape, an elliptical shape, or the like.

Furthermore, as illustrated in FIG. 4, each light emitting element 200 includes an anode electrode (first electrode) 202 provided on the substrate 300, a light emitting layer 204 that is laminated on the anode electrode 202 and emits light, a cathode electrode (second electrode) 206 that is laminated on the light emitting layer 204 and transmits light from the light emitting layer 204, and a protective film (first protective film) 208 that is laminated on the cathode electrode 206 and transmits light from the light emitting layer 204.

Specifically, the substrate 300 can be formed of a glass substrate such as high strain point glass, soda glass, borosilicate glass, forsterite, lead glass, or quartz glass, a semiconductor substrate such as amorphous silicon or polycrystalline silicon, a resin substrate such as polymethyl methacrylate, polyvinyl alcohol, polyvinyl phenol, polyether sulfone, polyimide, polycarbonate, polyethylene terephthalate, or polyethylene naphthalate, or the like.

Specifically, the anode electrodes 202 of the plurality of light emitting elements 200 in one subpixel 100 are electrically connected to each other, and more specifically, as illustrated on the right side of FIG. 7, the anode electrodes 202 of the respective light emitting elements 200 are integrated to form one shared electrode. In other words, the plurality of light emitting elements 200 in one subpixel 100 shares one common electrode 202.

Furthermore, the anode electrode 202 may also have a function as a reflection layer, and is preferably formed of a metal film having as high a reflectance as possible and a large work function in order to enhance light extraction efficiency. Examples of such a metal film include a metal film containing at least one of a simple substance and an alloy of metal elements such as chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). In addition, specific examples of the above-described alloy include an aluminum (Al) alloy such as an AlNi alloy or an AlCu alloy, and a silver (Ag) alloy such as an MgAg alloy. Further, the anode electrode 202 may be formed of a transparent conductive film such as indium tin oxide (ITO), indium zinc oxide (120), or zinc oxide (ZnO).

In addition, the light emitting layer 204 provided on the anode electrode 202 is made of an organic material or an inorganic material, and can emit white light. In addition, the light emitting layer 204 may include a hole injection layer (not illustrated) and a hole transport layer (not illustrated) provided adjacent to the anode electrode 202, and an electron transport layer (not illustrated) provided adjacent to the cathode electrode 206. In other words, the light emitting layer 204 can have a structure in which a hole injection layer, a hole transport layer, the light emitting layer 204, and an electron transport layer (not illustrated) are laminated from the anode electrode 202 side. Note that the hole injection layer functions as a layer for enhancing hole injection efficiency into the light emitting layer 204, and also functions as a buffer layer for suppressing leakage. The hole transport layer functions as a layer that enhances hole transport efficiency to the light emitting layer 204. In addition, in the light emitting layer 204, generation of an electric field causes recombination of electrons and holes, and can generate light. The electron transport layer functions as a layer that increases electron transport efficiency to the light emitting layer 204. Further, the light emitting layer 204 may have an electron injection layer (not illustrated) between the electron transport layer and the cathode electrode 206. The electron injection layer functions as a layer that enhances electron injection efficiency.

Note that, in the present embodiment, the configuration of the light emitting layer 204 is not limited to the above-described configuration, and layers other than the hole injection layer and the light emitting layer 204 can be provided as necessary. Furthermore, in the present embodiment, the light emitting layers 204 of the light emitting elements 200 of all the subpixels 100 may be formed to have the same structure or may be formed to have different structures, and is not particularly limited.

In addition, the cathode electrode 206 provided on the light emitting layer 204 is a transparent electrode having transparency to light generated in the light emitting layer 204, and in the following description, the transparent electrode also includes a semi-transparent electrode. The cathode electrode 206 can be formed of a metal film containing at least one of a simple substance or an alloy of a metal element such as aluminum (Al), magnesium (Mg), calcium (Ca), sodium (Na), or silver (Ag). In addition, specific examples of the alloy include an aluminum (Al) alloy such as an MgAg alloy or an AlLi alloy, and a silver (Ag) alloy. Further, the cathode electrode 206 may be formed of a transparent conductive film such as indium tin oxide (ITO), indium zinc oxide (IZO), or zinc oxide (ZnO).

In addition, the protective film 208 provided on the cathode electrode 206 is formed of a material having a high refractive index. For example, the protective film 208 is formed of a material having a refractive index of about 1.7 to 2.1 with respect to light having a wavelength of about 450 nm at room temperature, for example. The protective film 208 is formed of, for example, a nitride film such as silicon nitride (SiN), a transparent conductive film such as indium tin oxide (ITO), indium zinc oxide (IZO), or zinc oxide (ZnO), or a transparent organic film.

Then, as illustrated in FIG. 4, in the present embodiment, a protective film (second protective film) 210 constituting an interface for guiding light immediately above the light emitting element 200 together with the protective film 208 is embedded between the adjacent light emitting elements 200. Specifically, as illustrated in FIG. 4, in the present embodiment, the protective film 210 is embedded between the adjacent light emitting elements 200 and is provided so as to cover the light emitting elements 200. For example, as illustrated in FIG. 4, the protective film 210 is provided so as to fill between the adjacent light emitting elements 200 from the position of the upper surface of the protective film 208 to the position of the lower surface of the light emitting layer 204.

Furthermore, the protective film 210 is preferably formed of a material having a refractive index lower than that of the protective film 208, and is preferably formed of a material having a refractive index having a difference of, for example, 0.3 or more with respect to the protective film 208. The protective film 210 can be formed of, for example, an oxide film such as silicon oxide (SiO₂) or aluminum oxide (Al₂O₃), a resin film, or a cavity, that is, air (air gap).

In the present embodiment, by forming the protective films 208 and 210 from a material having a refractive index as described above, light from the light emitting layer 204 is diffracted many times at the boundary between the protective film 208 and the protective film 210, and can be confined in the protective film 208 and interfere with each other.

Furthermore, in the present embodiment, as illustrated in FIG. 4, the color filter 302 and the on-chip lens 304 are provided above the protective film 208 for each subpixel 100. In other words, in the present embodiment, the plurality of light emitting elements 200 included in one subpixel 100 shares one on-chip lens 304, and share one color filter 302 provided between the protective film 208 and the on-chip lens 304.

Specifically, the color filter 302 can be formed of a color filter that transmits a red wavelength component, a color filter that transmits a green wavelength component, or a color filter that transmits a blue wavelength component. For example, the color filter 302 can be formed of a material in which a pigment or a dye is dispersed in a transparent binder such as silicone. Furthermore, the on-chip lens 304 can be formed of a styrene resin, an acrylic resin, a styrene-acrylic copolymer resin, a siloxane resin, or the like.

As described above, in the present embodiment, the subpixel 100 includes the plurality of light emitting elements 200 having the width d of 400 nm to 800 nm, for example, and the protective film 210 embedded between the adjacent light emitting elements 200 is formed of a material having a refractive index lower than that of the protective film 208 of the light emitting element 200. Therefore, in the present embodiment, the protective film 208 and the protective film 210 form an interface for guiding light immediately above the light emitting element 200. As a result, in the present embodiment, the light from the light emitting layer 204 of the light emitting element 200 is diffracted many times at the boundary between the protective film 208 and the protective film 210 surrounding the protective film 208, and interferes in the protective film 208. Therefore, in the present embodiment, since the protective film 208 functions like a waveguide and guides more light from the light emitting layer 204 upward, the light extraction efficiency of the light emitting device 10 can be improved. Furthermore, in the present embodiment, since the subpixel 100 includes the plurality of light emitting elements 200 sharing one anode electrode 202, even in a case where the light emitting element 200 having a small width d is provided, it is possible to avoid lowering the aperture ratio. As a result, according to the present embodiment, the light extraction efficiency can be improved without reducing the aperture ratio.

Furthermore, in the present embodiment, since the subpixel 100 includes the plurality of light emitting elements 200, for example, even if one light emitting element 200 included in one subpixel 100 fails and does not emit light, it is possible to maintain the light emission of the subpixel 100 by the other light emitting elements 200 emitting light. Therefore, in the present embodiment, the operation of the light emitting device 10 can be made more stable.

Note that the present embodiment is not limited to the configuration illustrated on the right side of FIGS. 4 and 7, and the film thickness of each element constituting the subpixel 100 is not particularly limited, and can be appropriately selected according to desired characteristics.

### <3.2 Modification>

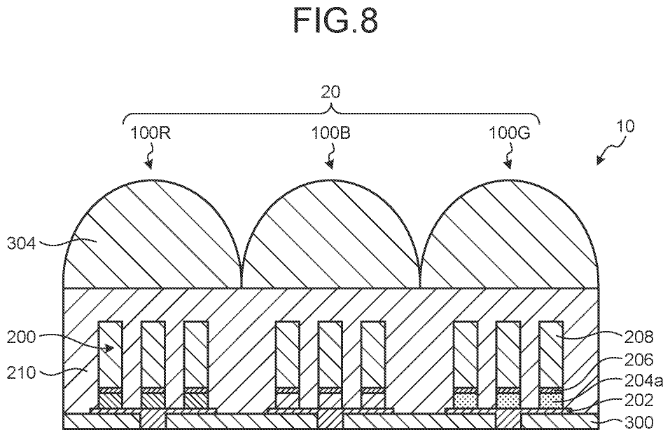

Next, a modification of the present embodiment will be described with reference to FIG. 8. FIG. 8 is a cross-sectional view for explaining an example of a configuration of a pixel according to a modification of the present embodiment, and corresponds to the cross-sectional view illustrated in FIG. 4.

As illustrated in FIG. 8, in the modification of the present embodiment, unlike the above-described present embodiment, the color filter 302 may not be provided between the protective film 208 and the on-chip lens 304. In the present modification, instead of the color filter 302, a light emitting layer 204a of each light emitting element 200 is made of an organic material or an inorganic material, and is formed of a layer capable of emitting any one of red light, green light, and blue light.

### <3.3 Manufacturing Method>

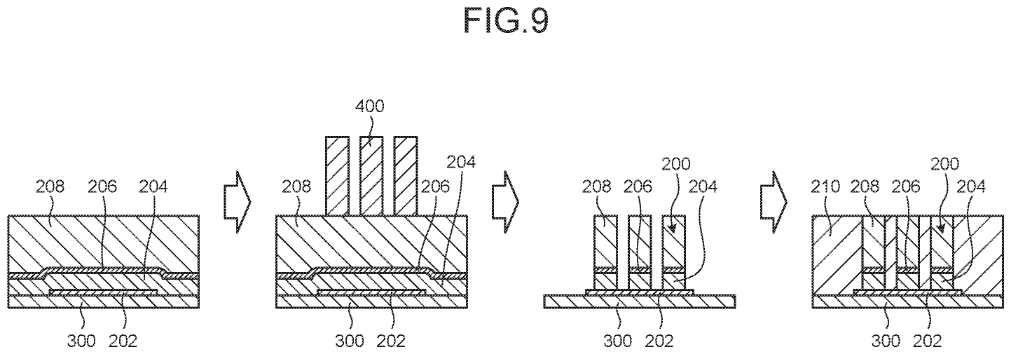

Next, a method for manufacturing the pixel 20 according to the present embodiment will be described with reference to FIG. 9. FIG. 9 is an explanatory diagram for explaining the method for manufacturing the pixel 20 of the present embodiment, and corresponds to the cross-sectional view of FIG. 4.

As illustrated on the left side of FIG. 9, a patterned anode electrode 202 is formed on a substrate 300, and a light emitting layer 204, a cathode electrode 206, and a protective film 208 are sequentially laminated on the anode electrode 202.

Next, as illustrated second from the left side in FIG. 9, a mask 400 having a predetermined pattern is formed on the protective film 208 by photolithography.

Furthermore, as illustrated in the third from the left side of FIG. 9, the lamination including the light emitting layer 204, the cathode electrode 206, and the protective film 208 is dry-etched according to the pattern of the mask 400, and the lamination is divided into a plurality of light emitting elements 200.

Then, as illustrated on the right side of FIG. 9, a protective film 210 is embedded between the divided light emitting elements 200. Furthermore, in the present embodiment, the structure illustrated in FIG. 4 can be obtained by forming a contact electrode (not illustrated), a color filter 302, and an on-chip lens 304 on the protective film 210 and the light emitting element 200.

### 4. Second Embodiment

### <4.1 Detailed Configuration>

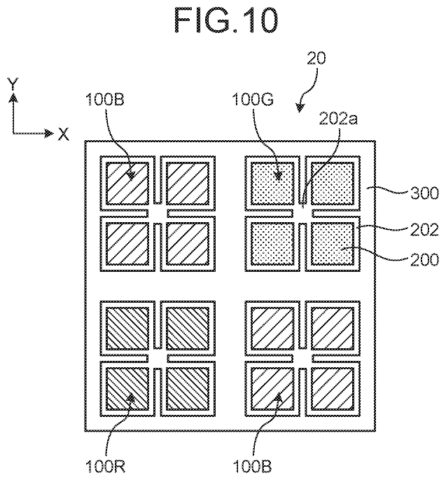

The pixel 20 according to the first embodiment of the present disclosure described above can be variously modified. Therefore, a modification of the planar configuration of the pixel 20 will be described as the second embodiment of the present disclosure with reference to FIG. 10. FIG. 10 is a plan view for explaining an example of the configuration of the pixel according to the second embodiment of the present disclosure, and corresponds to the plan view illustrated on the right side of FIG. 7.

In the first embodiment of the present disclosure described above, as illustrated on the right side of FIG. 7, in one subpixel 100, the plurality of light emitting elements 200 is provided on one anode electrode 202. However, the embodiment of the present disclosure is not limited to such a form, and the anode electrodes 202 of the plurality of light emitting elements 200 in one subpixel 100 is only required to be electrically connected to each other.

Specifically, as illustrated in FIG. 10, for example, in one subpixel 100, the anode electrodes 202 of the four light emitting elements 200 arranged in a square array (specifically, the light emitting element 200 is located at a position of each vertex of the square) are electrically connected to each other by a connection electrode 202a located at the center of the entirety of the four light emitting elements 200.

### <4.2 Modification>

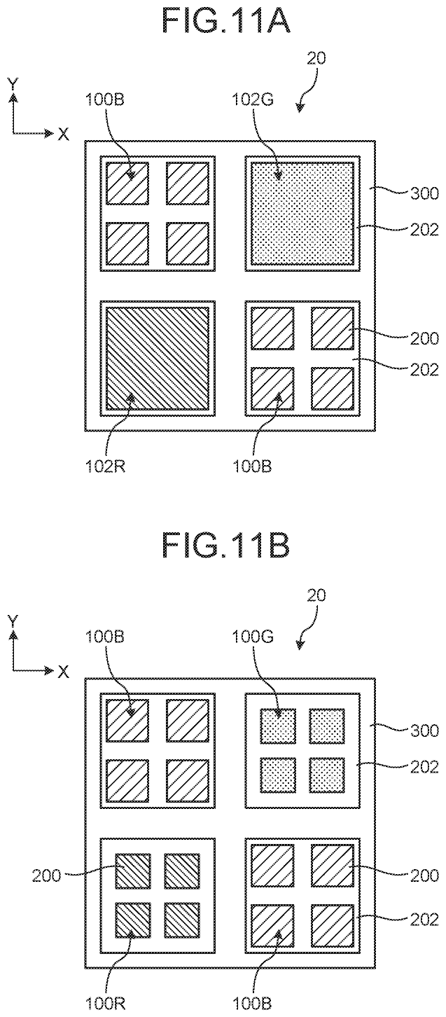

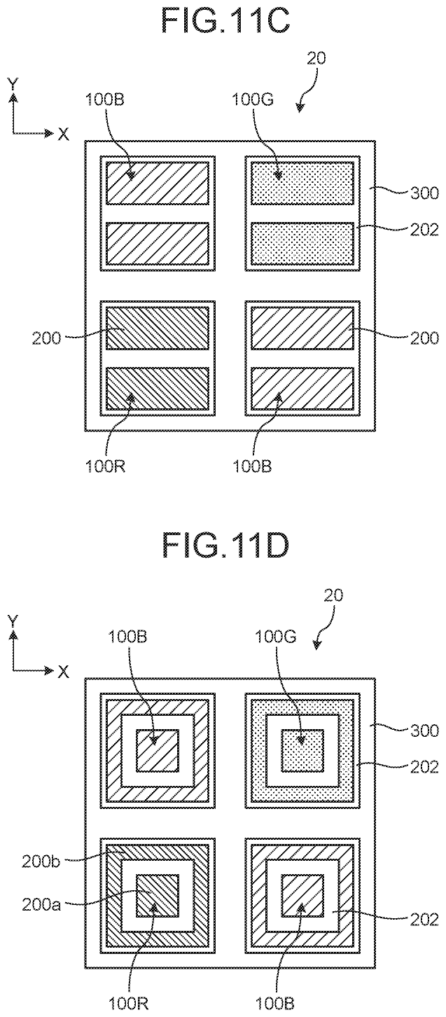

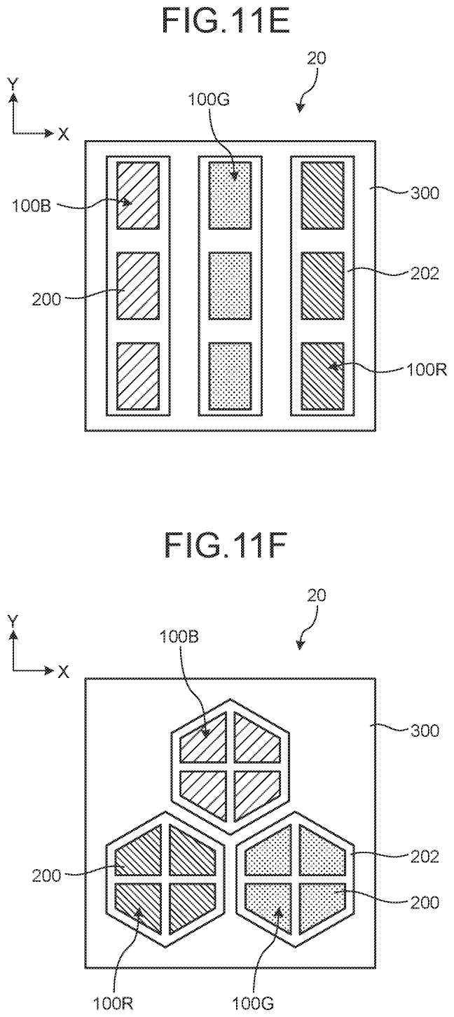

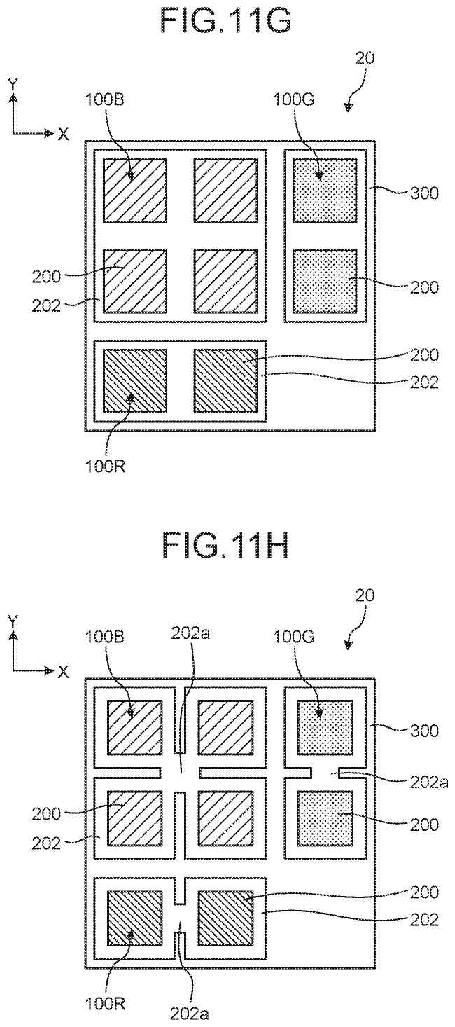

Furthermore, a modification of the present embodiment will be described with reference to FIGS. 11A to 11H, and FIGS. 11A to 11H are plan views for explaining an example of a configuration of a pixel according to the modification of the present embodiment.

### (Modification 1)

First, as illustrated in FIG. 11A, among the three types of subpixels 100 and 102 included in one pixel 20, one or two types of subpixels 100 (in FIG. 11A, a subpixel 100B that emits blue light) include a plurality of light emitting elements 200 similarly to the first embodiment. On the other hand, in the remaining subpixels 102 (in FIG. 11A, a subpixel 102R that emits red light and a subpixel 102G that emits green light), similarly to the comparative example, the plurality of light emitting elements 200 is not included, but one subpixel 102 is configured. In this way, according to the present modification, the light extraction efficiency can be adjusted according to the color of light.

### (Modification 2)

Next, as illustrated in FIG. 11B, among the three types of subpixels 100 included in one pixel 20, the sizes of the light emitting elements 200 of one or two types of subpixels 100 (in FIG. 11B, a subpixel 100B that emits blue light) may be different from the sizes of the light emitting elements 200 of the remaining subpixels 100 (in FIG. 11B, a subpixel 100R that emits red light and a subpixel 100G that emits green light). Specifically, in the example illustrated in FIG. 11B, the size of the light emitting element 200 of the subpixel 100B that emits blue light is larger than the sizes of the light emitting elements 200 of the subpixels 100R and 100G that emit red light and green light. In this way, according to the present modification, the light extraction efficiency can be adjusted according to the color of light.

### (Modification 3)

Next, as illustrated in FIG. 11C, the subpixel 100 is not limited to being configured by the four light emitting elements 200 arrayed in a square array, and may be configured by two rectangular light emitting elements 200 arrayed along the Y direction in the drawing. In this way, according to the present modification, the degree of spread of light along the X direction and the Y direction in the drawing can be adjusted. For example, in the example illustrated in FIG. 11C, since the width of the light emitting element 200 is wide in the X direction, the radiation angle of light is large, and since the width of the light emitting element 200 is narrow in the Y direction, the radiation angle of light is small. Note that, in the present modification, the subpixel 100 may include two light emitting elements 200 arranged along the X direction in the drawing.

### (Modification 4)

Next, as illustrated in FIG. 11D, the subpixel 100 may include a light emitting element 200a located inside and a light emitting element 200b surrounding the light emitting element 200a. In the example illustrated in FIG. 11D, since the width of one side of the light emitting element 200a on the inner side is wider than the width of the light emitting element 200b located on the outer side, the light easily spreads, but since the width of the light emitting element 200b located on the outer side is narrow, the spread of the light can be suppressed in the entire subpixel 100. In this way, according to the present modification, the intensity of light from the subpixel 100 can be made uniform.

### (Modification 5)

Furthermore, in the present modification, one subpixel 100 is not limited to being configured by four light emitting elements 200 arranged in a square array, and may be configured by, for example, three light emitting elements 200 arranged along the Y direction in the drawing as illustrated in FIG. 11E. Note that, in the present modification, the subpixel 100 may include three light emitting elements 200 arranged along the X direction in the drawing. Furthermore, in the present modification, one subpixel 100 may be configured by a plurality of light emitting elements 200 arranged in a polygonal array (specifically, the light emitting element 200 is located at a position of each vertex of the polygon). In this way, according to the present modification, the degree of spread of light along the X direction and the Y direction in the drawing can be adjusted.

### (Modification 6)

Furthermore, in the present modification, one subpixel 100 is not limited to being configured by the plurality of rectangular light emitting elements 200, and may be configured by, for example, a plurality of light emitting elements 200 having a polygonal shape in plan view as illustrated in FIG. 11F. Specifically, in the example illustrated in FIG. 11F, the light emitting element 200 has a pentagonal shape. In this way, according to the present modification, the degree of spread of light along a desired direction in the drawing can be adjusted.

### (Modification 7)

Furthermore, in the present modification, the three types of subpixels 100 included in one pixel 20 may not have the same number of light emitting elements 200. For example, in the example illustrated in FIGS. 11G and 11H, among the three types of subpixels 100 included in one pixel 20, the number of light emitting elements 200 of one or two types of subpixels 100 (in FIGS. 11G and 11H, the subpixel 100B that emits blue light) is 4, but the number of light emitting elements 200 of the remaining subpixels 100 (in FIGS. 11G and 11H, a subpixel 100R that emits red light and a subpixel 100G that emits green light) is 2. In this way, according to the present modification, the light extraction efficiency can be adjusted according to the color of light.

### 5. Third Embodiment

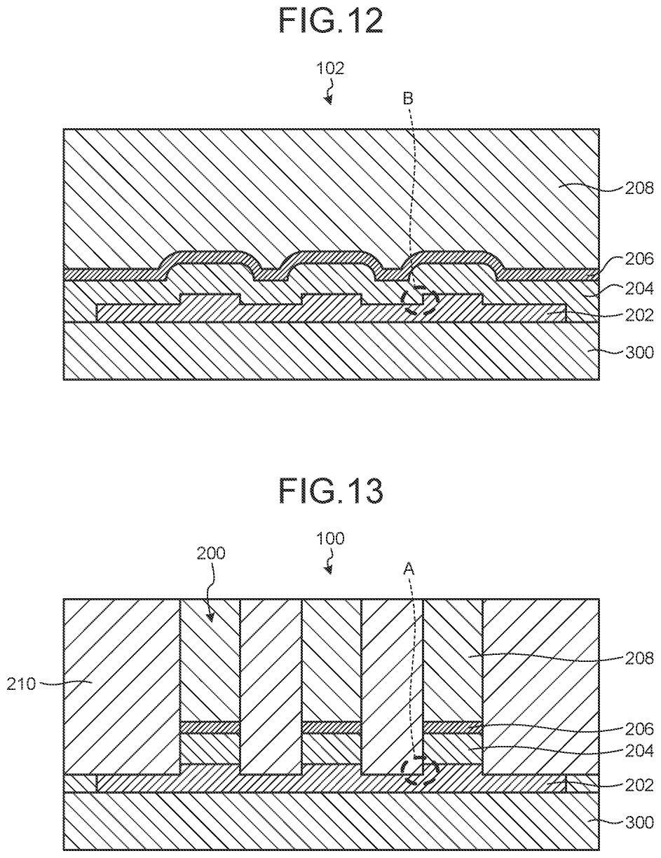

Next, a modification of the cross-sectional configuration of the subpixel 100 will be described as the third embodiment of the present disclosure with reference to FIGS. 12 and 13. FIG. 12 is a cross-sectional view for explaining an example of a configuration of a subpixel 102 according to a comparative example, FIG. 13 is a cross-sectional view for explaining an example of a configuration of a subpixel 100 according to the present embodiment, and these drawings correspond to the cross-sectional view of FIG. 4.

Meanwhile, on the surface of the metal, there is a wave called surface plasmon (also referred to as surface plasmon polariton), which is collective oscillation by free electrons in the metal. Therefore, also on the surface of the anode electrode 202, since the light from the light emitting layer 204 moves along the surface of the anode electrode 202 due to such surface plasmon, the light is not emitted upward of the light emitting element 200 and is finally damaged as thermal energy. That is, due to the surface plasmon, the light from the light emitting layer 204 is impaired without being extracted (plasmon loss).

Therefore, in order to suppress plasmon loss, it has been studied to form periodic nanostructures (plasmonic crystals) on the surface of the anode electrode 202. By utilizing the diffraction effect of the periodic nanostructure, the vector of the surface plasmon along the surface direction of the anode electrode 202 is reduced, and the light from the light emitting layer 204 is suppressed from moving along the surface of the anode electrode 202. More specifically, in the present embodiment, periodic steps are formed on the surface of the anode electrode 202 in order to suppress plasmon loss.

Here, as illustrated in FIG. 12, it is considered to form periodic steps in the anode electrode 202 in the subpixel 102 according to the comparative example. In this case, the light emitting layer 204, the cathode electrode 206, and the protective film 208 are sequentially laminated on the anode electrode 202 on which the periodic steps are formed.

However, in the structure as illustrated in FIG. 12, since the protrusion portion of the anode electrode 202 and the light emitting layer 204 are displaced in the left-right direction in FIG. 12, a voltage is applied to the light emitting layer 204 from the side surface of the above-described protrusion of the anode electrode 202, and light emitted from the subpixel 102 spreads. In addition, plasmon loss may occur on the bottom surface of the recess portion of the anode electrode 202 in contact with the light emitting layer 204. Furthermore, there is a possibility that electric field concentration occurs at an end portion of the protrusion portion of the anode electrode 202 covered with the light emitting layer 204 (region indicated by B in FIG. 12), and in such a case, a failure of the subpixel 102 may occur.

Therefore, in the third embodiment of the present disclosure, in order to suppress the plasmon loss, a periodic step is formed in the anode electrode (common electrode) 202 of the light emitting element 200, as described above. Specifically, in the present embodiment, a protrusion (first region) where the light emitting layer 204 is laminated and a recess (second region) where the light emitting layer 204 is not laminated are formed on the upper surface of the anode electrode 202. Furthermore, in the present embodiment, the protective film 210 is provided so as to be embedded from the position of the upper surface of the protective film 208 to a position lower than the lower surface of the light emitting layer 204 between the adjacent light emitting elements 200.

In the case of the present embodiment, the anode electrode 202, the light emitting layer 204, the cathode electrode 206, and the protective film 208 are sequentially laminated, and then the anode electrode 202 is partially etched to be divided into a plurality of light emitting elements 200. Furthermore, by embedding the protective film 210 between the divided light emitting elements 200, a structure as illustrated in FIG. 13 can be obtained. That is, in the present embodiment, the light emitting layer 204 can be formed on the anode electrode 202 having periodic steps by self-alignment.

In the present embodiment, no deviation occurs in the left-right direction in FIG. 13 between the protrusion portion of the anode electrode 202 and the light emitting layer 204, and as a result, no voltage is applied to the light emitting layer 204 from the side surface of the above-described protrusion of the anode electrode 202. As a result, in the present embodiment, it is possible to suppress the light emitted from the subpixel 102 from easily spreading. In addition, in the present embodiment, since the recess portion of the anode electrode 202 is not in contact with the light emitting layer 204, plasmon loss on the bottom surface of the recess portion of the anode electrode 202 with respect to light from the light emitting layer 204 can be suppressed. Furthermore, since the end portion of the protrusion portion of the anode electrode 202 (region indicated by A in FIG. 13) is not covered with the light emitting layer 204, even if electric field concentration occurs, failure of the light emitting element 200 can be avoided.

As described above, according to the present embodiment, it is possible to suppress the light emitted from the subpixel 102 from easily spreading and the occurrence of the failure of the light emitting element 200 while suppressing the plasmon loss.

### 6. Fourth Embodiment

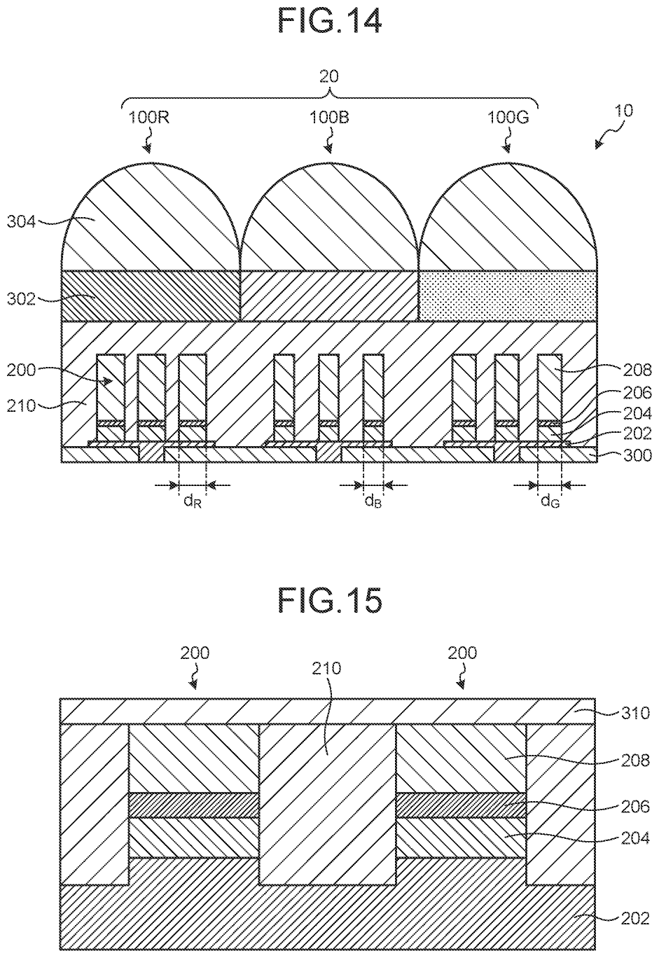

Furthermore, in the embodiment of the present disclosure, the width d of the light emitting element 200 may be changed according to the color of the light emitted from the subpixel 100. Therefore, the fourth embodiment of the present disclosure in which the width d of the light emitting element 200 is changed according to the color of the light emitted from the subpixel 100 will be described with reference to FIG. 14. FIG. 14 is a cross-sectional view for explaining an example of the configuration of the pixel 20 according to the present embodiment, and corresponds to the cross-sectional view of FIG. 4.

As illustrated in FIG. 14, in the present embodiment, the width d of the light emitting element 200 differs according to the color of the light emitted from the subpixel 100. Specifically, by narrowing the width d of the light emitting element 200 according to the wavelength of light, light from the light emitting layer 204 can be more effectively interfered in the protective film 208, and the protective film 208 can guide the light upward, so that the light extraction efficiency can be improved. In the present embodiment, the light extraction efficiency can be further improved by narrowing the width d of the light emitting element 200 so as to be close to the interference limit of each light.

Specifically, as illustrated in FIG. 14, in the present embodiment, the width de of the adjacent light emitting elements 200 in the subpixel 100G that emits green light is narrower than the width de of the adjacent light emitting elements 200 in the subpixel 100B that emits blue light, and is wider than the width dr of the adjacent light emitting elements 200 in the subpixel 100R that emits red light. According to the present embodiment, by changing the width d of the light emitting element 200 according to the color of the light emitted from the subpixel 100, the interference effect of the light in the protective film 208 can be further enhanced, and the light extraction efficiency can be further improved.

### 7. Fifth Embodiment

### <7.1 Detailed Configuration>

Next, a modification of the common contact electrode 310 electrically connecting the cathode electrodes 206 of the plurality of light emitting elements 200 will be described as the fifth embodiment of the present disclosure with reference to FIG. 15. FIG. 15 is a cross-sectional view for explaining an example of the configuration of the light emitting element 200 according to the present embodiment, and corresponds to the cross-sectional view of FIG. 4.

In the example illustrated in FIG. 15, an example of the common contact electrode 310 in a case where the protective film 208 is formed of a conductive material is illustrated. In such a case, the common contact electrode 310 is provided so as to cover the protective film 208, and the cathode electrodes 206 of the plurality of adjacent light emitting elements 200 can be electrically connected by electrically connecting the protective film 208.

### <7.2 Modification>

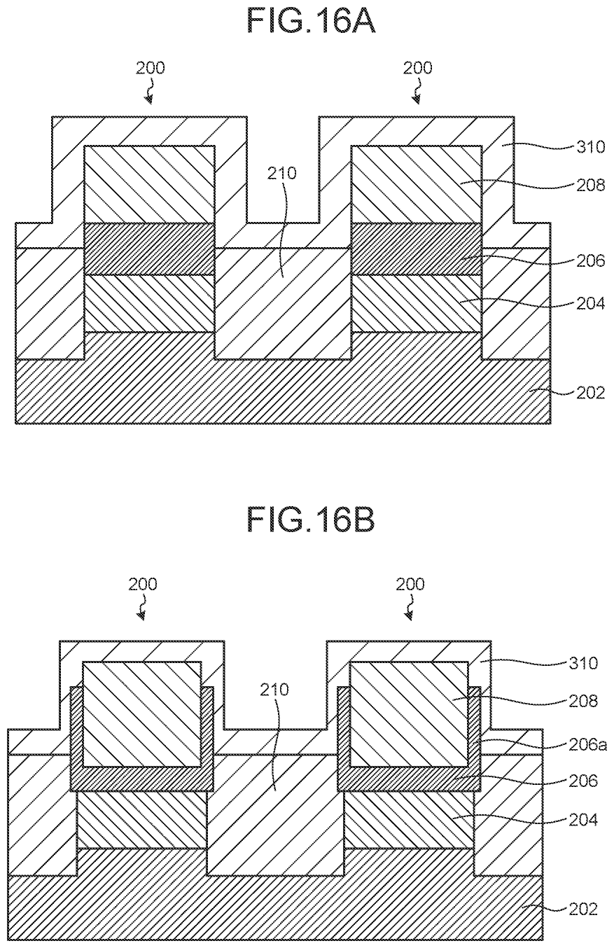

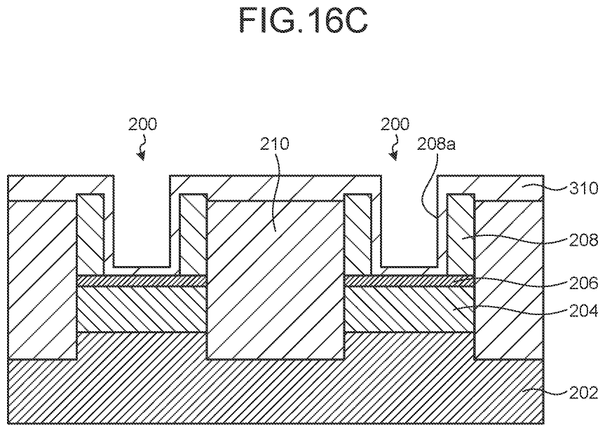

In addition, an example of the common contact electrode 310 in a case where the protective film 208 is formed of a non-conductive material (that is, the insulating material) will be described as a modification of the present embodiment with reference to FIGS. 16A to 16C. FIGS. 16A to 16C are cross-sectional views for explaining an example of a configuration of a light emitting element 200 according to a modification of the present embodiment, and correspond to the cross-sectional view of FIG. 4.

First, in the example illustrated in FIG. 16A, the protective film 210 is provided so as to be embedded from the position of the lower surface of the protective film 208 to a position lower than the lower surface of the light emitting layer 204 between the adjacent light emitting elements 200. Further, the above-described common contact electrode 310 is provided so as to cover the entire protective film 208 and to cover a part of the side surface of the cathode electrode 206. In other words, the common contact electrode 310 is electrically connected to a part of the side surface of the cathode electrode 206. According to the present modification, the cathode electrodes 206 of the plurality of adjacent light emitting elements 200 can be electrically connected by the common contact electrode 310.

In addition, in the example illustrated in FIG. 16B, a wall 206a is formed of a conductive material so as to surround the periphery of the cathode electrode 206, and a protective film 208 is further laminated in a region surrounded by the wall 206a. Then, in the present modification, the common contact electrode 310 is formed so as to cover the entire protective film 208 surrounded by the wall 206a. According to the present modification, the cathode electrodes 206 of the plurality of adjacent light emitting elements 200 can be electrically connected by the common contact electrode 310.

Furthermore, in the example illustrated in FIG. 16C, the protective film 208 has an opening 208a that exposes the upper surface of the cathode electrode 206, and the common contact electrode 310 is provided so as to cover the inside of the opening 208a. According to the present modification, the cathode electrodes 206 of the plurality of adjacent light emitting elements 200 can be electrically connected by the common contact electrode 310.

### 8. Sixth Embodiment

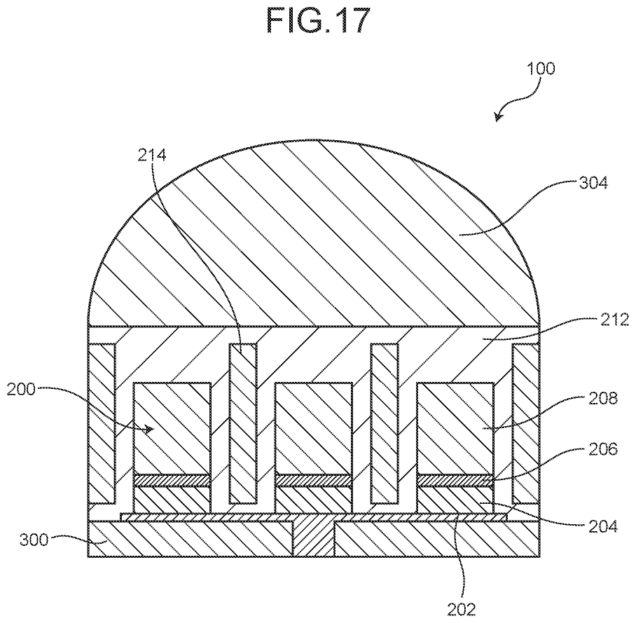

In the present disclosure, the protective film (second protective film) 210 is only required to be provided so as to form an interface for guiding light immediately above the light emitting element 200. That is, the present disclosure is not limited to the configuration in which the protective film 210 is embedded between the adjacent light emitting elements 200 and is provided so as to cover the light emitting elements 200 as in each of the embodiments described above. Therefore, the sixth embodiment of the present disclosure in which a protective film (second protective film) 214 has a different form from the protective film 210 in the previous embodiments will be described with reference to FIGS. 17 to 19. FIGS. 17 to 19 are cross-sectional views for explaining an example of a configuration of a pixel according to the present embodiment.

In the present embodiment, as illustrated in FIG. 17, each subpixel 100 includes a plurality of light emitting elements 200 similarly to the embodiments described above. Then, each light emitting element 200 includes an anode electrode 202 provided on the substrate 300, a light emitting layer 204 laminated on the anode electrode 202, a cathode electrode 206 laminated on the light emitting layer 204, and a protective film 208 laminated on the cathode electrode 206. Note that, since each layer constituting the light emitting element 200 is formed of the material described in the first embodiment, the description thereof is omitted here.

Also in the present embodiment, it is preferable that the light emitting element 200 has a rectangular shape when viewed from above the substrate 300 (in plan view), and the length of one side of the light emitting element 200 is about 400 nm to 800 nm. Note that, also in the present embodiment, the shape of the light emitting element 200 in plan view is not limited to the rectangular shape, and may be, for example, a polygonal shape, a circular shape, an elliptical shape, or the like.

Furthermore, in the present embodiment, as illustrated in FIG. 17, a protective film 214 constituting an interface for guiding light immediately above the light emitting element 200 is embedded between the adjacent light emitting elements 200. In addition, in the present embodiment, as illustrated in FIG. 17, it is preferable that the upper surface of the protective film 214 is higher than the position of the upper surface of the protective film 208, and the lower surface of the protective film 214 is lower than the position of the upper surface of the light emitting layer 204.

The protective film 214 is formed of a material having a refractive index lower than that of the protective film 208 and a refractive index lower than that of a protective film (third protective film) 212 described later, similarly to the embodiments described above. The protective film 214 is formed of a material having a refractive index lower than those of the protective films 208 and 212, and is preferably formed of a material having a refractive index having a difference of, for example, 0.3 or more from the protective films 208 and 212. The protective film 214 can be formed of, for example, an oxide film such as silicon oxide (SiO₂) or aluminum oxide (Al₂O₃), a resin film, or a cavity, that is, air (air gap).

Alternatively, the protective film 214 may be formed of a metal film. The protective film 214 can be formed using, for example, a metal such as aluminum (Al), silver (Ag), copper (Cu), titanium (Ti), or tungsten (W), or an alloy containing these as a main component.

Furthermore, in the present embodiment, the interval between the adjacent protective films 214 is preferably, for example, 400 nm to 800 nm.

In addition, in the present embodiment, as illustrated in FIG. 17, the protective film 208 and the protective film 210 are covered with a protective film (third protective film) 212. The protective film 212 is formed of a material having the same or lower refractive index than the protective film 208. For example, the protective film 212 is formed of a nitride film such as silicon nitride (SiN), an oxide film such as silicon oxide (SiO₂) or aluminum oxide (Al₂O₃), a resin film, or the like.

As described above, also in the present embodiment, the protective film 214 embedded between the adjacent light emitting elements 200 is formed of a material having a lower refractive index than the protective films 208 and 212 or a metal film. Therefore, in the present embodiment, the protective film 214 and the protective film 212 form an interface for guiding light immediately above the light emitting element 200. As a result, in the present embodiment, the light from the light emitting layer 204 of the light emitting element 200 is diffracted many times at the interface between the protective film 214 and the protective film 212, and interferes in the protective film 208. Alternatively, in the present embodiment, light from the light emitting layer 204 of the light emitting element 200 is reflected many times by the protective film 214 formed of a metal film, and interferes in the protective film 208. Therefore, in the present embodiment, since the protective film 208 functions like a waveguide and guides more light from the light emitting layer 204 upward, the light extraction efficiency of the light emitting device 10 can be improved. Furthermore, in the present embodiment, since the subpixel 100 includes the plurality of light emitting elements 200 sharing one anode electrode 202, even in a case where the light emitting element 200 having a small width d is provided, it is possible to avoid lowering the aperture ratio. As a result, according to the present embodiment, the light extraction efficiency can be improved without reducing the aperture ratio.

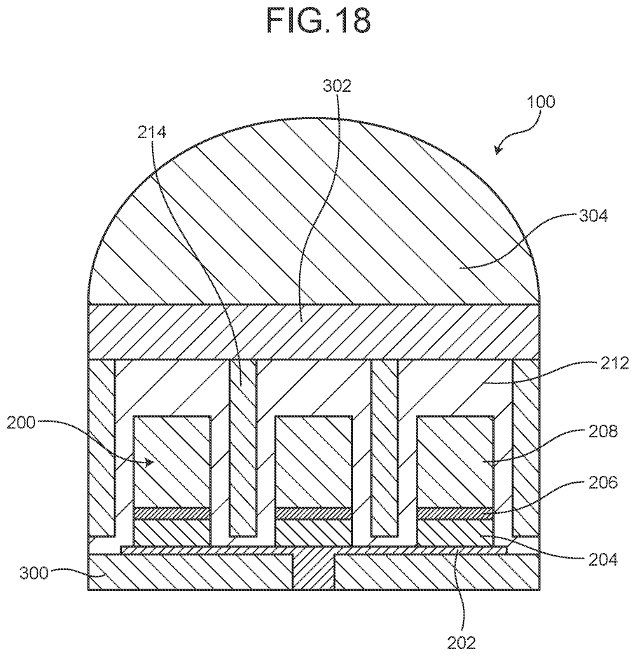

Furthermore, in the present embodiment, as illustrated in FIG. 18, the protective film 214 is preferably provided such that the upper surface of the protective film 214 reaches the height of the lower surface of the color filter 302 on the protective film (third protective film) 212 described later. In this way, the light from the light emitting layer 204 of the light emitting element 200 can be more guided toward the upper side of the light emitting element 200.

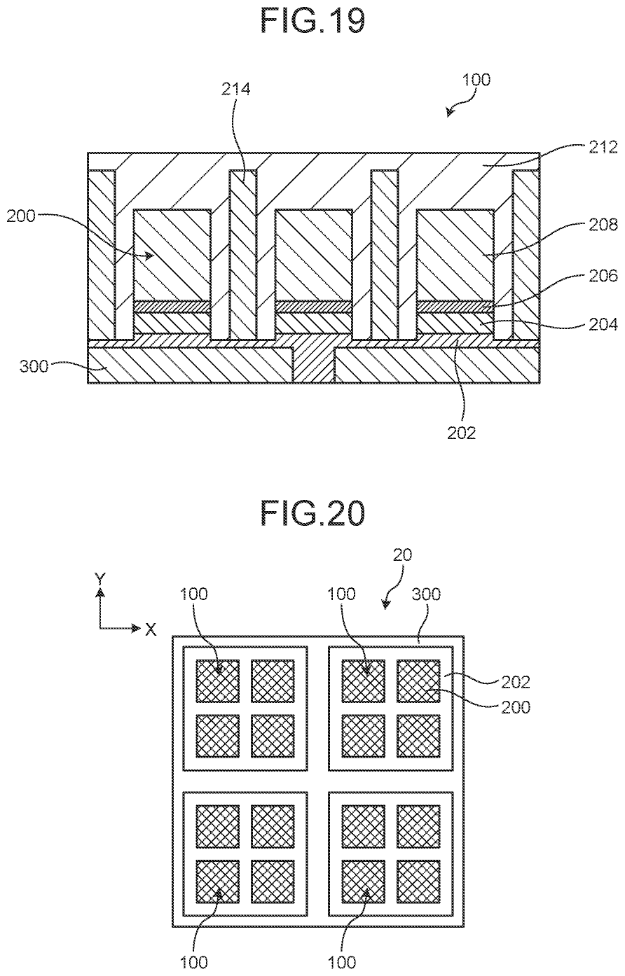

Further, in the present embodiment, as illustrated in FIG. 19, the anode electrode 202 may have a periodic step, similarly to the third embodiment of the present disclosure, and in this case, the light emitting layer 204 is provided at the protrusion portion of the anode electrode 202. Then, in the present embodiment, the protective film 214 is preferably provided such that the lower surface of the protective film 214 reaches the surface of the recess portion of the anode electrode 202. In this way, the light from the light emitting layer 204 of the light emitting element 200 can be more guided toward the upper side of the light emitting element 200.

### 9. Seventh Embodiment

Next, a modification of the planar configuration of the pixel 20 will be described as the seventh embodiment of the present disclosure with reference to FIGS. 20 to 23. FIGS. 20 to 23 are plan views for explaining an example of the configuration of the pixel 20 according to the present embodiment. Specifically, FIGS. 20 to 23 illustrate a case where the pixel 20 is cut parallel to the plane of the substrate 300 at the height of the light emitting layer 204.

In the present embodiment, as illustrated in FIG. 20, one pixel (pixel) 20 may include a plurality of subpixels 100 that emits light of the same color. Furthermore, each subpixel 100 may include a plurality of light emitting elements 200 that emits light of the same color.

In the present embodiment, as illustrated in FIG. 21, each light emitting element 200 may have a circular shape when viewed from above the substrate 300.

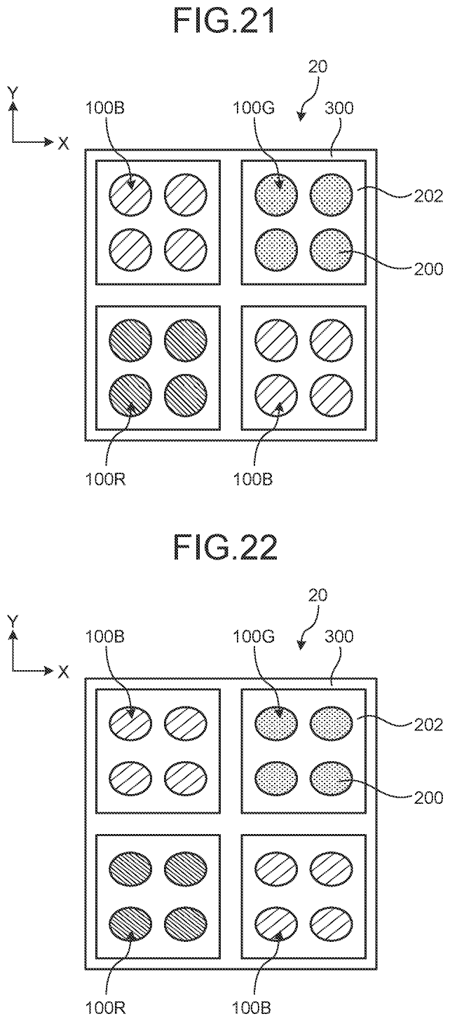

Furthermore, in the present embodiment, as illustrated in FIG. 22, each light emitting element 200 may have an elliptical shape when viewed from above the substrate 300.

Furthermore, in the present embodiment, as illustrated in FIG. 23, one pixel 20 may have a plurality of subpixels 100 having light emitting elements 200 having planar shapes different from each other. Specifically, for example, as illustrated in FIG. 23, the subpixels 100G and 100R have a circular light emitting element 200, and the subpixels 100B-1 and 100B-2 have an elliptical light emitting element 200. Note that, in the present embodiment, the light emitting element 200 is not limited to having a different shape for each subpixel 100. In the present embodiment, for example, the plurality of light emitting elements 200 may have different shapes in one subpixel 100, or the light emitting elements 200 may have different shapes for each pixel 20.

Furthermore, in the example of FIG. 23, the light emitting element 200 of the subpixel 100B-1 has an elliptical shape having a major axis along the X direction in the drawing, and the light emitting element 200 of the subpixel 100B-2 has an elliptical shape having a major axis along the Y direction in the drawing. Note that, in the present embodiment, the major axis of the ellipse may have an inclination with respect to the X direction or the Y direction. Furthermore, in the present embodiment, the major axis of the ellipse of the light emitting element 200 is not limited to having a different inclination for each subpixel 100. In the present embodiment, for example, in one subpixel 100, the major axes of the ellipses of the plurality of light emitting elements 200 may have different inclinations, or the major axes of the ellipses of the light emitting elements 200 may have different inclinations for each pixel 20.

That is, in the present disclosure, the shape of the light emitting element 200 in plan view is not limited to the rectangular shape, and can be various shapes such as a polygonal shape, a circular shape, and an elliptical shape, for example.

### 10. Summary

As described above, in the embodiment of the present disclosure, the subpixel 100 includes the plurality of light emitting elements 200 having the width d of 400 nm to 800 nm, for example, and the protective film 210 embedded between the adjacent light emitting elements 200 is formed of a material having a lower refractive index than the protective film 208 of the light emitting element 200. Therefore, in the present embodiment, the light from the light emitting layer 204 of the light emitting element 200 is diffracted many times at the interface between the protective film 208 and the protective film 210, and interferes in the protective film 208. Alternatively, in the embodiment of the present disclosure, the protective film 214 embedded between the adjacent light emitting elements 200 is formed of a material having a refractive index lower than that of the protective film 208 of the light emitting element 200 and the protective film 212 covering the protective films 208 and 214. Therefore, in the present embodiment, the light from the light emitting layer 204 of the light emitting element 200 is diffracted many times at the interface between the protective film 212 and the protective film 214, and interferes in the protective film 208. Schematically, in the present embodiment, the protective film 214 buried between the adjacent light emitting elements 200 is formed of a metal film. Therefore, in the present embodiment, the light from the light emitting layer 204 of the light emitting element 200 is reflected many times by the protective film 214 and interferes in the protective film 208. Therefore, in the present embodiment, since the protective film 208 functions like a waveguide and guides more light from the light emitting layer 204 upward, the light extraction efficiency of the light emitting device 10 can be improved. Furthermore, in the present embodiment, since the subpixel 100 includes the plurality of light emitting elements 200 sharing one anode electrode 202, even in a case where the light emitting element 200 having a small width d is provided, it is possible to avoid lowering the aperture ratio. As a result, according to the present embodiment, the light extraction efficiency can be improved without reducing the aperture ratio.

Furthermore, in the present embodiment of the present disclosure, since the subpixel 100 includes the plurality of light emitting elements 200, for example, even if one light emitting element 200 included in one subpixel 100 fails and does not emit light, it is possible to maintain the light emission of the subpixel 100 by the other light emitting elements 200 emitting light. Therefore, in the present embodiment, the operation of the light emitting device 10 can be made more stable.

Furthermore, the light emitting device 10 according to the embodiment of the present disclosure can be manufactured by using a method, a device, and conditions used for manufacturing a general semiconductor device. That is, the light emitting device 10 according to the present embodiment can be manufactured using an existing method for manufacturing a semiconductor device.

Note that examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high frequency sputtering method, and the like), an ion plating method, a laser ablation method, a molecular beam epitaxy (MBE) method, and a laser transfer method. In addition, examples of the CVD method include a plasma CVD method, a thermal CVD method, an organic metal (MO) CVD method, and a photo CVD method. Further, other methods include an electrolytic plating method, an electroless plating method, and a spin coating method; immersion method; cast method; micro-contact printing; drop cast method; various printing methods such as a screen printing method, an inkjet printing method, an offset printing method, a gravure printing method, and a flexographic printing method; stamping method; spray method; examples of the coating method include various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Furthermore, examples of the patterning method include chemical etching such as shadow mask, laser transfer, and photolithography, and physical etching using ultraviolet rays, laser, or the like. In addition, examples of the planarization technique include a chemical mechanical polishing (CMP) method, a laser planarization method, a reflow method, and the like.

### 11. Modification

### <11.1 Modification 1>

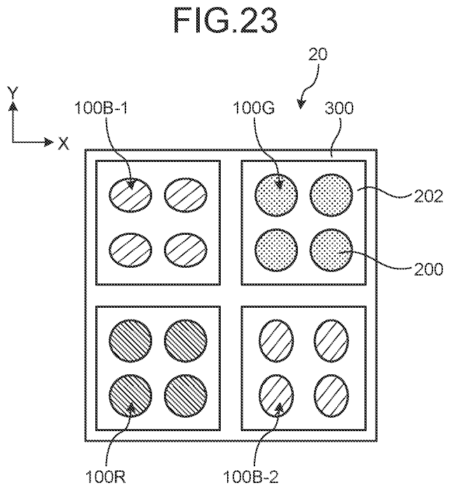

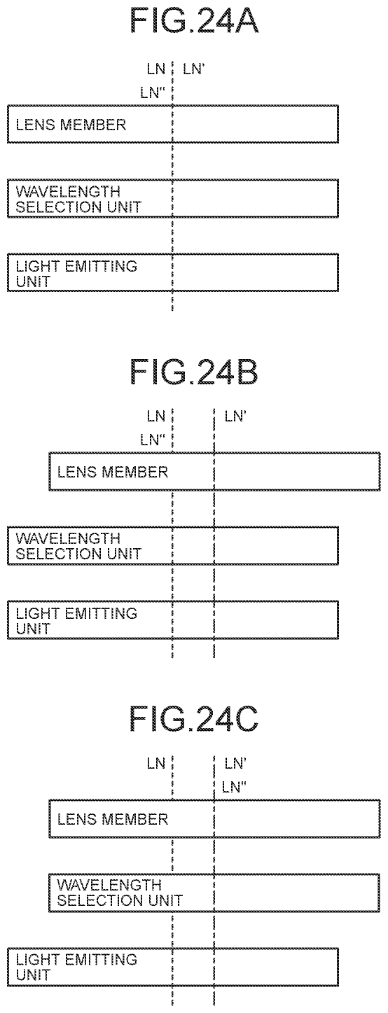

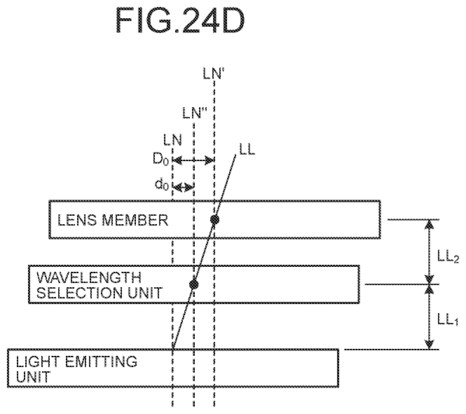

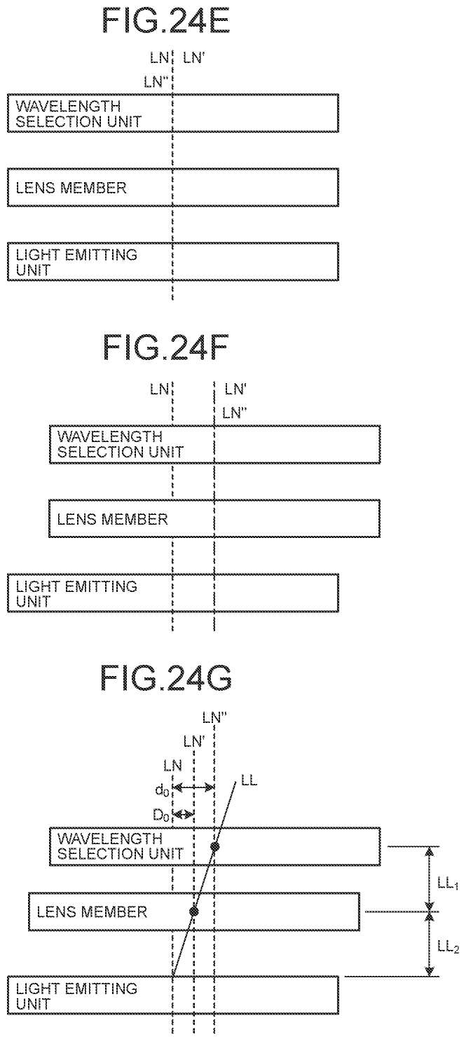

Next, as a modification of the embodiment of the present disclosure, a modification of the relationship between the normal line IN passing through the center of the subpixel 100 (specifically, the center of the plurality of light emitting elements 200 included in one subpixel 100), the normal line LN′ passing through the center of the lens member (specifically, the on-chip lens 304), and the normal line LN″ passing through the center of the wavelength selection unit (specifically, the color filter 302) will be described with reference to FIGS. 24A to 24G. FIGS. 24A to 24G are conceptual diagrams for explaining a relationship among a normal line LN passing through the center of the light emitting unit, a normal line LN′ passing through the center of the lens member, and a normal line LN″ passing through the center of the wavelength selection unit. Note that, in the following description, the center of the subpixel 100 is referred to as the center of the light emitting unit.

In the embodiment of the present disclosure, the size of the wavelength selection unit (for example, the color filter 302) may be appropriately changed according to the light emitted from the subpixel 100. Furthermore, in a case where the light absorption layer (black matrix layer) is provided between the light absorption layer (black matrix layer) and the wavelength selection unit (for example, the color filter 302) of the adjacent subpixel 100, the size of the light absorption layer (black matrix layer) may be appropriately changed according to the light emitted from the subpixel 100. Furthermore, the size of the wavelength selection unit (for example, the color filter 302) may be appropriately changed according to the distance (offset amount) do between the normal line passing through the center of the subpixel 100 and the normal line passing through the center of the color filter 302. The planar shape of the wavelength selection unit (for example, the color filter 302) may be the same as, similar to, or different from the planar shape of the lens member (for example, the on-chip lens 304).

For example, as illustrated in FIG. 24A, a normal line LN passing through the center of the light emitting unit, a normal line IN″ passing through the center of the wavelength selection unit, and a normal line LN′ passing through the center of the lens member may coincide with each other. In other words, the distance (offset amount) Do between the normal line passing through the center of the light emitting unit and the normal line passing through the center of the lens member and the distance (offset amount) do between the normal line passing through the center of the light emitting unit and the normal line passing through the center of the wavelength selection unit can be equal to 0 (zero).

Furthermore, for example, as illustrated in FIG. 24B, the normal line LN passing through the center of the light emitting unit and the normal line LN″ passing through the center of the wavelength selection unit coincide with each other, but the normal line LN passing through the center of the light emitting unit and the normal line LN″ passing through the center of the wavelength selection unit may not coincide with the normal line LN′ passing through the center of the lens member. In other words, D₀≠d₀=0 may be satisfied.

Furthermore, for example, as illustrated in FIG. 24C, the normal line LN passing through the center of the light emitting unit may not coincide with the normal line LN″ passing through the center of the wavelength selection unit and the normal line LN′ passing through the center of the lens member, and the normal line LN″ passing through the center of the wavelength selection unit may coincide with the normal line LN′ passing through the center of the lens member. In other words, D₀=d₀>0 may be satisfied.

Furthermore, for example, as illustrated in FIG. 24D, a normal line LN passing through the center of the light emitting unit may not match a normal line LN″ passing through the center of the wavelength selection unit and a normal line LN′ passing through the center of the lens member, and the normal line LN′ passing through the center of the lens member may not match the normal line LN passing through the center of the light emitting unit and the normal line LN″ passing through the center of the wavelength selection unit. Here, the center of the wavelength selection unit (indicated by a black square in FIG. 24D) is preferably located on a straight line LL connecting the center of the light emitting unit and the center of the lens member (indicated by a black circle in FIG. 24D). Specifically, when a distance from the center of the light emitting unit in the thickness direction to the center of the wavelength selection unit is LL₁, and a distance from the center of the wavelength selection unit in the thickness direction to the center of the lens member is LL₂, D₀>d₀>0, and it is preferable that d₀:D₀=LL₁:(LL₁+LL₂) is satisfied in consideration of manufacturing variations.

In addition, the lamination relationship between the wavelength distal end portion and the lens member may be interchanged. In such a case, for example, as illustrated in FIG. 24E, the normal line LN passing through the center of the light emitting unit, the normal line LN″ passing through the center of the wavelength selection unit, and the normal line LN′ passing through the center of the lens member may coincide with each other. In other words, D₀=d₀=0 may be satisfied.

Furthermore, for example, as illustrated in FIG. 24F, the normal line LN passing through the center of the light emitting unit may not match the normal line LN″ passing through the center of the wavelength selection unit and the normal line LN′ passing through the center of the lens member, and the normal line LN″ passing through the center of the wavelength selection unit may match the normal line LN′ passing through the center of the lens member. In other words, D₀=d₀>0 may be satisfied.

Furthermore, as illustrated in FIG. 24G which is a conceptual diagram, a normal line LN passing through the center of the light emitting unit may not match a normal line LN″ passing through the center of the wavelength selection unit and a normal line LN′ passing through the center of the lens member, and the normal line LN′ passing through the center of the lens member may not match the normal line LN passing through the center of the light emitting unit and the normal line LN″ passing through the center of the wavelength selection unit. Here, the center of the wavelength selection unit is preferably located on a straight line LL connecting the center of the light emitting unit and the center of the lens member. Specifically, when a distance from the center of the light emitting unit in the thickness direction to the center of the wavelength selection unit (indicated by a black square in FIG. 24G) is LL₁, and a distance from the center of the wavelength selection unit in the thickness direction to the center of the lens member (indicated by a black circle in FIG. 24G) is LL₂, d₀>D₀>0, and it is preferable that D₀:d₀=LL₂:(LL₁+LL₂) is satisfied in consideration of manufacturing variations.

### <11.2 Modification 2>

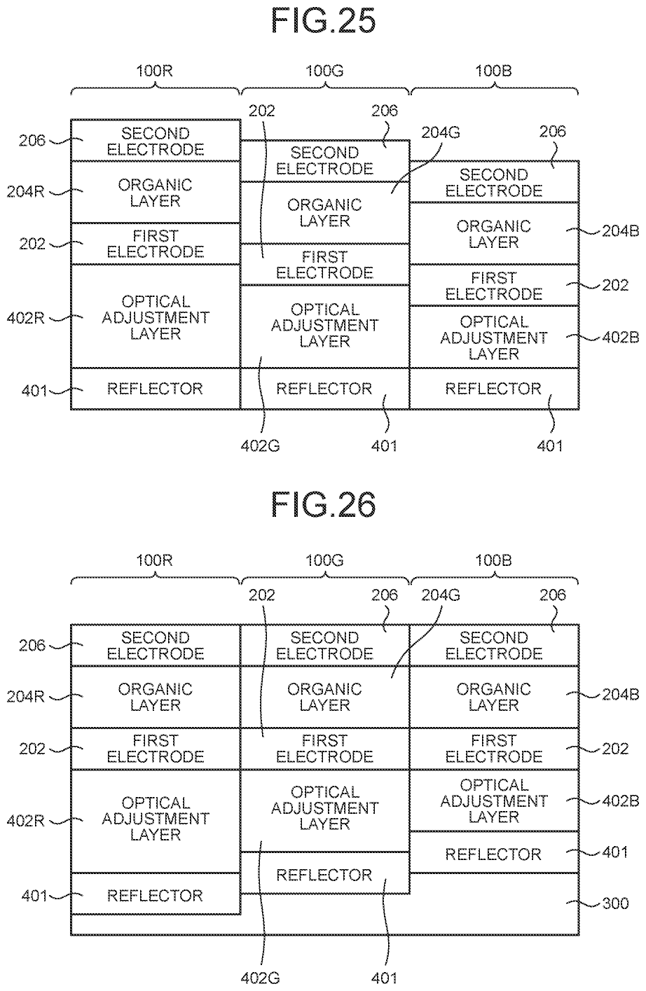

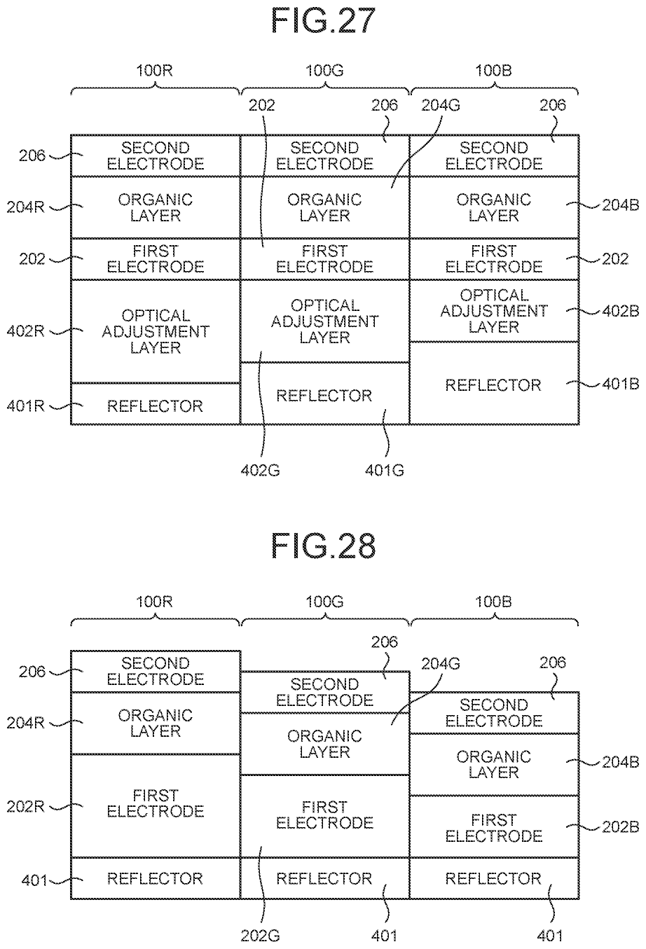

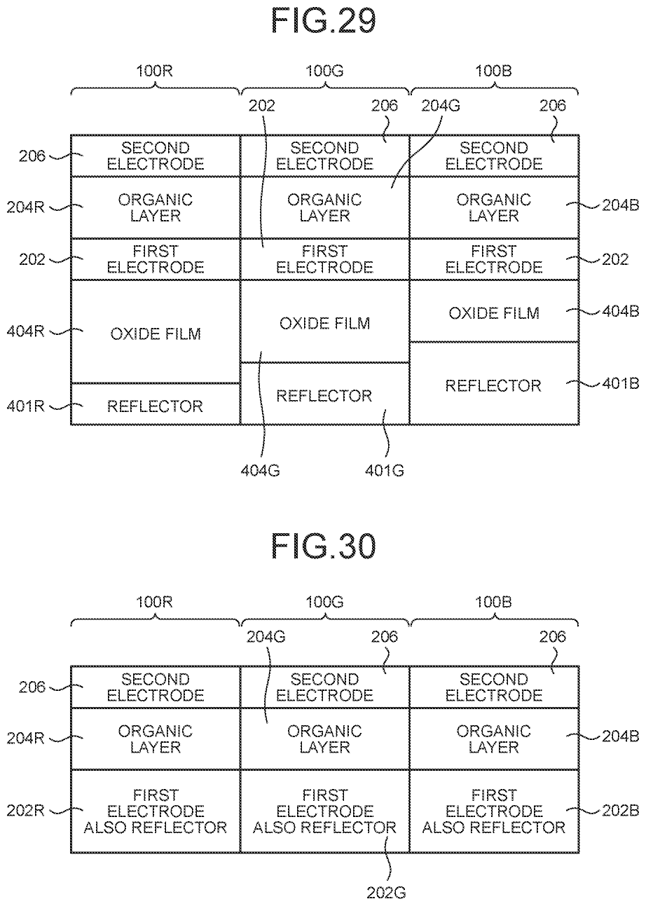

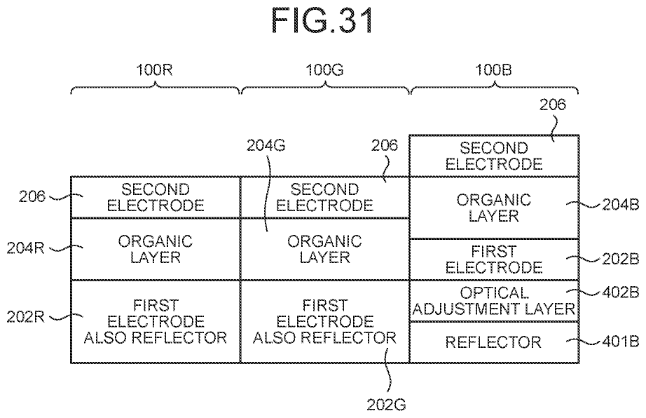

The subpixel 100 (specifically, the light emitting element 200) used in the light emitting device according to the embodiment of the present disclosure described above may have a resonator structure that causes light generated in the light emitting layer 204 to resonate. Hereinafter, the resonator structure will be described with reference to FIGS. 25 to 31. FIG. 25 is a schematic cross-sectional view for explaining a first example of the resonator structure, FIG. 26 is a schematic cross-sectional view for explaining a second example of the resonator structure, and FIG. 27 is a schematic cross-sectional view for explaining a third example of the resonator structure. In addition, FIG. 28 is a schematic cross-sectional view for explaining a fourth example of the resonator structure, and FIG. 29 is a schematic cross-sectional view for explaining a fifth example of the resonator structure. Furthermore, FIG. 30 is a schematic cross-sectional view for explaining a sixth example of the resonator structure, and FIG. 31 is a schematic cross-sectional view for explaining a seventh example of the resonator structure.

### Resonator Structure: First Example

FIG. 25 is a schematic cross-sectional view for explaining a first example of the resonator structure. In the first example, the first electrode (for example, an anode electrode) 202 is formed with a common film thickness in each subpixel 100. It similarly applies to the second electrode (for example, a cathode electrode) 206.

As illustrated in FIG. 25, a reflector 401 is disposed below the first electrode 202 of the subpixel 100 with an optical adjustment layer 402 interposed therebetween. A resonator structure that resonates light generated by the organic layer (specifically, the light emitting layer) 204 is formed between the reflector 401 and the second electrode 206.

The reflector 401 is formed with a common film thickness in each subpixel 100. The film thickness of the optical adjustment layer 402 varies depending on the color to be displayed by the subpixel 100. Since optical adjustment layers 402R, 402G, and 402B have different film thicknesses, it is possible to set an optical distance at which optimum resonance occurs for a wavelength of light corresponding to a color to be displayed.

In the example illustrated in FIG. 25, the upper surfaces of the reflectors 401 in the subpixels 100R, 100G, and 100B are arranged so as to be aligned. As described above, since the film thickness of the optical adjustment layer 402 varies depending on the color to be displayed by the subpixel 100, the position of the upper surface of the second electrode 206 varies depending on the types of the subpixels 100R, 100G, and 100B.

The reflector 401 can be formed using, for example, a metal such as aluminum (Al), silver (Ag), or copper (Cu), or an alloy containing these as a main component.

The optical adjustment layer 402 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a laminated film of a plurality of materials. Furthermore, the number of laminated layers may be different according to the type of the subpixel 100.

The first electrode 202 can be formed using, for example, a transparent conductive material such as indium tin oxide (ITO), indium zinc oxide (IZO), or zinc oxide (ZnO).

The second electrode 206 preferably functions as a semi-transmission reflection film. The second electrode 206 can be formed using magnesium (Mg), silver (Ag), a magnesium-silver alloy (MgAg) containing these as a main component, an alloy containing an alkali metal or an alkaline earth metal, or the like.

### Resonator Structure: Second Example

FIG. 26 is a schematic cross-sectional view for explaining a second example of the resonator structure. Also in the second example, the first electrode 202 and the second electrode 206 are formed with a common film thickness in each subpixel 100.

Then, also in the second example, the reflector 401 is disposed below the first electrode 202 of the subpixel 100 with the optical adjustment layer 402 interposed therebetween. A resonator structure that resonates light generated by the organic layer 204 is formed between the reflector 401 and the second electrode 206. Similarly to the first example, the reflector 401 is formed with a common film thickness in each subpixel 100, and the film thickness of the optical adjustment layer 402 varies depending on the color to be displayed by the subpixel 100.

In the first example illustrated in FIG. 25, the upper surfaces of the reflectors 401 in the subpixels 100R, 100G, and 100B are arranged so as to be aligned, and the positions of the upper surfaces of the second electrodes 206 are different depending on the types of the subpixels 100R, 100G, and 100B.

On the other hand, in the second example illustrated in FIG. 26, the upper surfaces of the second electrodes 206 are arranged so as to be aligned in the subpixels 100R, 100G, and 100B. In order to align the upper surfaces of the second electrodes 206, the upper surfaces of the reflectors 401 in the subpixels 100R, 100G, and 100B are arranged differently according to the types of the subpixels 100R, 100G, and 100B. Therefore, the lower surface of the reflector 401 has a stair shape according to the types of the subpixels 100R, 100G, and 100B.

Materials and the like constituting the reflector 401, the optical adjustment layer 402, the first electrode 202, and the second electrode 206 are similar to the contents described in the first example, and thus the description thereof is omitted.

### Resonator Structure: Third Example

FIG. 27 is a schematic cross-sectional view for explaining a third example of the resonator structure. Also in the third example, the first electrode 202 and the second electrode 206 are formed with a common film thickness in each subpixel 100.

Then, also in the third example, the reflector 401 is disposed below the first electrode 202 of the subpixel 100 with the optical adjustment layer 402 interposed therebetween. A resonator structure that resonates light generated by the organic layer 204 is formed between the reflector 401 and the second electrode 206. Similarly to the first example and the second example, the film thickness of the optical adjustment layer 402 varies depending on the color to be displayed by the subpixel 100. Then, similarly to the second example, the positions of the upper surfaces of the second electrodes 206 are arranged so as to be aligned in the subpixels 100R, 100G, and 100B.

In the second example illustrated in FIG. 26, in order to align the upper surfaces of the second electrodes 206, the lower surface of the reflector 401 has a stair shape according to the types of the subpixels 100R, 100G, and 100B.

On the other hand, in the third example illustrated in FIG. 27, the film thickness of the reflector 401 is set to be different according to the types of the subpixels 100R, 100G, and 100B. More specifically, the film thickness is set such that the lower surfaces of reflectors 401R, 401G, and 401B are aligned.

Materials and the like constituting the reflector 401, the optical adjustment layer 402, the first electrode 202, and the second electrode 206 are similar to the contents described in the first example, and thus the description thereof is omitted.

### Resonator Structure: Fourth Example

FIG. 28 is a schematic cross-sectional view for explaining a fourth example of the resonator structure.

In the first example illustrated in FIG. 25, the first electrode 202 and the second electrode 206 of the subpixel 100 are formed with a common film thickness. Then, the reflector 401 is disposed below the first electrode 202 of the subpixel 100 with the optical adjustment layer 402 interposed therebetween.

On the other hand, in the fourth example illustrated in FIG. 28, the optical adjustment layer 402 is omitted, and the film thickness of the first electrode 202 is set to be different according to the types of the subpixels 100R, 100G, and 100B.

The reflector 401 is formed with a common film thickness in each subpixel 100. The film thickness of the first electrode 202 varies depending on the color to be displayed by the subpixel 100. Since the first electrodes 202R, 202G, and 202B have different film thicknesses, it is possible to set an optical distance that generates optimum resonance for the wavelength of light according to the color to be displayed.

Materials and the like constituting the reflector 401, the first electrode 202, and the second electrode 206 are similar to the contents described in the first example, and thus description thereof is omitted.

### Resonator Structure: Fifth Example

FIG. 29 is a schematic cross-sectional view for explaining a fifth example of the resonator structure.

In the first example illustrated in FIG. 25, the first electrode 202 and the second electrode 206 are formed with a common film thickness in each subpixel 100. Then, the reflector 401 is disposed below the first electrode 202 of the subpixel 100 with the optical adjustment layer 402 interposed therebetween.

On the other hand, in the fifth example illustrated in FIG. 29, the optical adjustment layer 402 is omitted, and instead, an oxide film 404 is formed on the surface of the reflector 401. The film thickness of the oxide film 404 was set to be different according to the types of the subpixels 100R, 100G, and 100B.

The film thickness of the oxide film 404 varies depending on the color to be displayed by the subpixel 100. Since oxide films 404R, 404G, and 404B have different film thicknesses, it is possible to set an optical distance at which optimum resonance occurs for a wavelength of light corresponding to a color to be displayed.

The oxide film 404 is a film obtained by oxidizing the surface of the reflector 401, and is made of, for example, aluminum oxide, tantalum oxide, titanium oxide, magnesium oxide, zirconium oxide, or the like. The oxide film 404 functions as an insulating film for adjusting an optical path length (optical distance) between the reflector 401 and the second electrode 206.

The oxide film 404 having different film thicknesses depending on the types of the subpixels 100R, 100G, and 100B can be formed, for example, as follows.

First, the electrolytic solution is filled in the container, and the substrate on which the reflector 401 is formed is immersed in the electrolytic solution. Further, the electrode is disposed so as to face the reflector 401.

Then, a positive voltage is applied to the reflector 401 with reference to the electrode, and the reflector 401 is anodized. The film thickness of the oxide film due to the anodization is proportional to the voltage value with respect to the electrode. Therefore, anodization is performed in a state where voltages corresponding to the types of the subpixels 100R, 100G, and 100B are applied to the reflectors 401R, 401G, and 401B, respectively. As a result, the oxide films 404 having different film thicknesses can be collectively formed.

Materials and the like constituting the reflector 401, the first electrode 202, and the second electrode 206 are similar to the contents described in the first example, and thus description thereof is omitted.

### Resonator Structure: Sixth Example

FIG. 30 is a schematic cross-sectional view for explaining a sixth example of the resonator structure. In the sixth example, the subpixel 100 is configured by laminating a first electrode 202, an organic layer 204, and a second electrode 206. However, in the sixth example, the first electrode 202 is formed to function as both an electrode and a reflector. The first electrode (also serving as a reflector) 202 is formed of a material having an optical constant selected according to the type of the subpixels 100R, 100G, and 100B. Since the phase shift by the first electrode (also serving as a reflector) 202 is different, it is possible to set an optical distance that generates optimum resonance for the wavelength of light according to the color to be displayed.

The first electrode (also serving as a reflector) 202 can be made of a single metal such as aluminum (Al), silver (Ag), gold (Au), or copper (Cu), or an alloy containing these as a main component. For example, the first electrode (also serving as a reflector) 202R of the subpixel 100R may be formed of copper (Cu), and the first electrode (also serving as a reflector) 202G of the subpixel 100G and the first electrode (also serving as a reflector) 202B of the subpixel 100B may be formed of aluminum.

The materials and the like constituting the second electrode 206 are similar to the contents described in the first example, and thus the description thereof will be omitted.

### Resonator Structure: Seventh Example

FIG. 31 is a schematic cross-sectional view for explaining a seventh example of the resonator structure. In the seventh example, basically, the sixth example is applied to the subpixels 100R and 100G, and the first example is applied to the subpixel 100B. Also in this configuration, it is possible to set an optical distance that causes optimum resonance for the wavelength of light according to the color to be displayed.

The first electrodes (also serving as reflectors) 202R and 202G used for the subpixels 100R and 100G can be made of a single metal such as aluminum (Al), silver (Ag), gold (Au), or copper (Cu), or an alloy containing these as a main component.

Materials and the like constituting the reflector 401B, the optical adjustment layer 402B, and the first electrode 202B used for the subpixel 100B are similar to the contents described in the first example, and thus description thereof is omitted.

### 12. Application Example

For example, the technology according to the present disclosure may be applied to a display unit or the like of various electronic devices. Therefore, an example of an electronic device to which the present technology can be applied will be described below.

### Specific Example 1

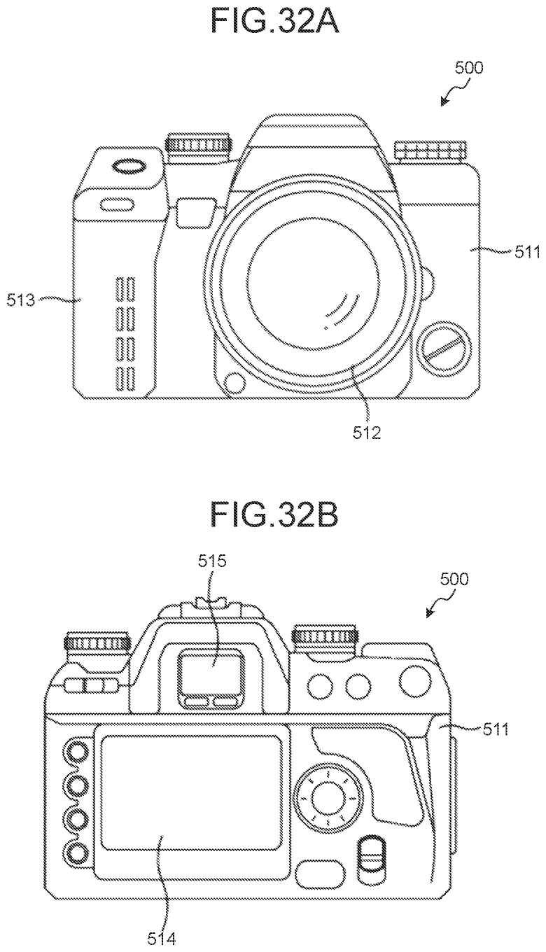

FIG. 32A is a front view illustrating an example of an external appearance of a digital still camera 500, and FIG. 32B is a rear view illustrating an example of an external appearance of the digital still camera 500. The digital still camera 500 is of a lens interchangeable single lens reflex type, and includes an interchangeable imaging lens unit (interchangeable lens) 512 substantially at the center in front of a camera main body portion (camera body) 511, and a grip portion 513 to be held by a photographer on the front left side.

A monitor 514 is provided at a position shifted to the left from the center of the back surface of the camera main body portion 511. An electronic view finder (eyepiece window) 515 is provided above the monitor 514. By looking into the electronic view finder 515, the photographer can determine the composition by visually recognizing the optical image of the subject guided from the imaging lens unit 512. As the monitor 514 and the electronic view finder 515, the light emitting device 10 according to the embodiment of the present disclosure can be used.

### Specific Example 2

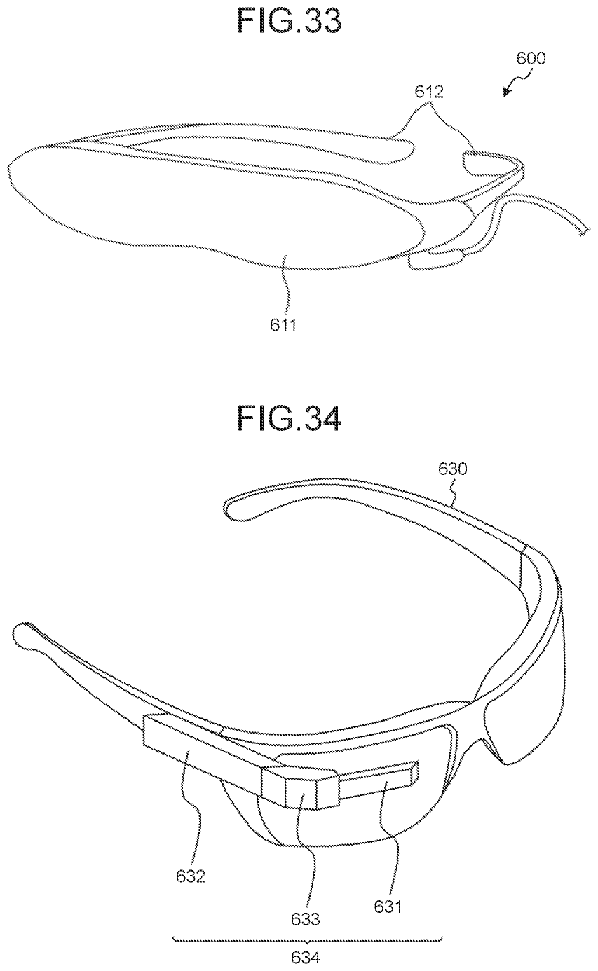

FIG. 33 is an external view of a head mounted display 600. The head mounted display 600 includes, for example, ear hooking portions 612 to be worn on the head of the user on both sides of the glass-shaped display unit 611. In the head mounted display 600, the light emitting device 10 according to the embodiment of the present disclosure can be used as the display unit 611.

### Specific Example 3

FIG. 34 is an external view of a see-through head mounted display 634. The see-through head mounted display 634 includes a main body portion 632, an arm 633, and a lens barrel 631.

The main body portion 632 is connected to the arm 633 and glasses 630. Specifically, an end portion of the main body portion 632 in the long side direction is coupled to the arm 633, and one side of the side surface of the main body portion 632 is coupled to the glasses 630 via a connecting member. Note that the main body portion 632 may be directly mounted on the head of the human body.

The main body portion 632 incorporates a control board for controlling the operation of the see-through head mounted display 634 and a display unit. The arm 633 connects the main body portion 632 and the lens barrel 631 and supports the lens barrel 631. Specifically, the arm 633 is coupled to the end portion of the main body portion 632 and the end portion of the lens barrel 631, and fixes the lens barrel 631. Furthermore, the arm 633 incorporates a signal line for communicating data related to an image provided from the main body portion 632 to the lens barrel 631.

The lens barrel 631 projects image light provided from the main body portion 632 via the arm 633 toward the eyes of the user wearing the see-through head mounted display 634 through the eyepiece. In the see-through head mounted display 634, the light emitting device 10 according to the embodiment of the present disclosure can be used for the display unit of the main body portion 632.

### Specific Example 4

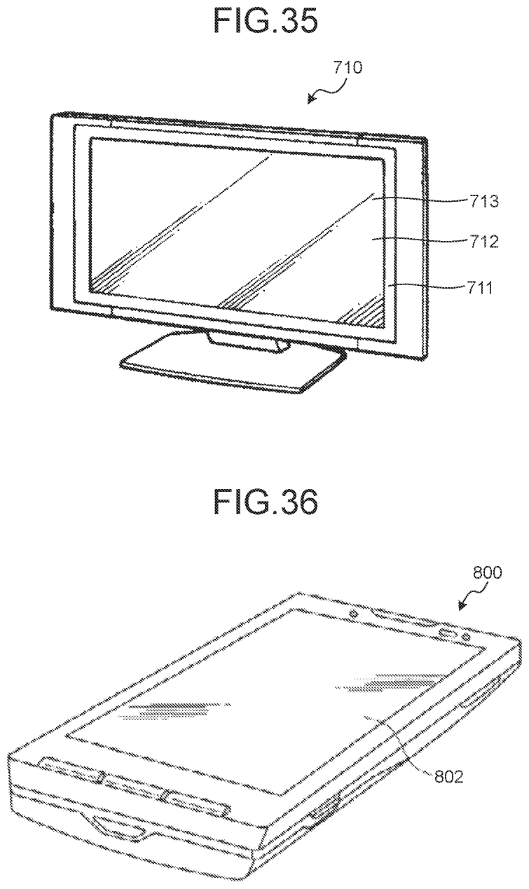

FIG. 35 illustrates an example of an external appearance of television apparatus 710. The television apparatus 710 includes, for example, a video display screen unit 711 including a front panel 712 and a filter glass 713, and the video display screen unit 711 includes the light emitting device 10 according to the embodiment of the present disclosure.

### Specific Example 5

FIG. 36 illustrates an example of an external appearance of a smartphone 800. The smartphone 800 includes a display unit 802 that displays various types of information, an operation unit including a button that receives an operation input by the user, and the like. The above-described display unit 802 can be the light emitting device 10 according to the present embodiment.

### Specific Example 6

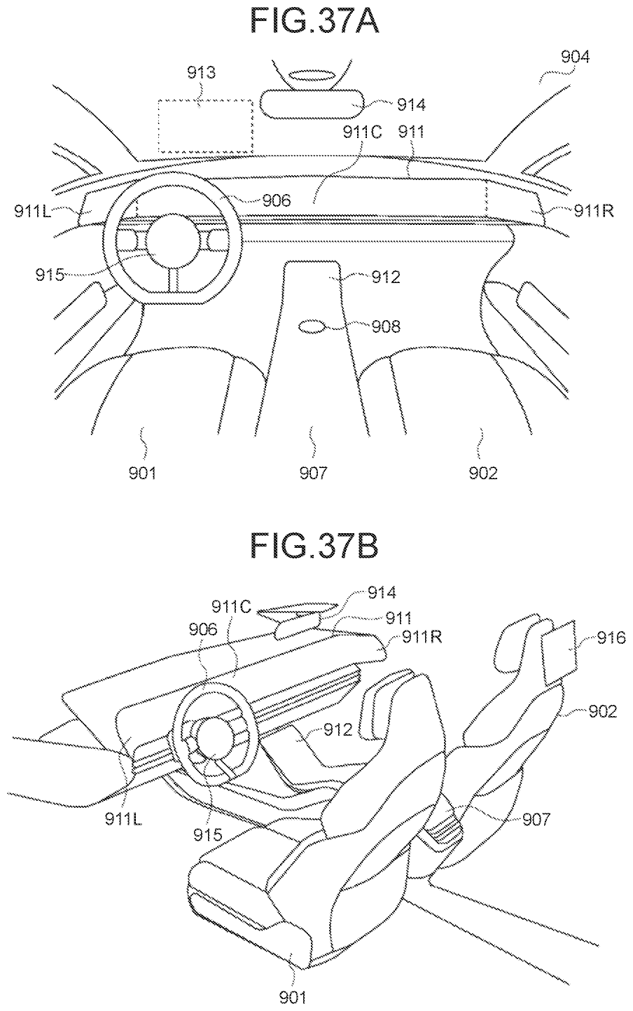

FIGS. 37A and 37B are diagrams illustrating an internal configuration of an automobile having a light emitting device 10 according to an embodiment of the present disclosure as a display device. Specifically, FIG. 37A is a diagram illustrating a state of the inside of the automobile from the rear to the front of the automobile, and FIG. 37B is a diagram illustrating a state of the inside of the automobile from the oblique rear to the oblique front of the automobile.

The automobile illustrated in FIGS. 37A and 37B has a center display 911, a console display 912, a head-up display 913, a digital rear mirror 914, a steering wheel display 915, and a rear entertainment display 916. The light emitting device 10 according to the embodiments of the present disclosure can be applied to some or all of these displays.

The center display 911 is disposed on a center console 907 at a position facing the driver's seat 901 and a passenger seat 902. FIGS. 37A and 37B illustrate an example of the center display 911 having a horizontally long shape extending from the driver's seat 901 side to the passenger seat 902 side, but the screen size and the arrangement place of the center display 911 are arbitrary. The center display 911 can display information detected by various sensors (not illustrated). As a specific example, the center display 911 can display a captured image captured by an image sensor, a distance image to an obstacle in front of or on a side of the automobile measured by a time of flight (ToF) sensor, a passenger's body temperature detected by an infrared sensor, and the like. The center display 911 can be used to display, for example, at least one of safety related information, operation related information, a life log, health related information, authentication/identification related information, and entertainment related information.

The safety related information is information such as doze detection, looking-away detection, mischief detection of a child riding together, presence or absence of wearing of a seat belt, and detection of leaving of an occupant, and is information detected by, for example, a sensor (not illustrated) superimposed on the back side of the center display 911. The operation related information detects a gesture related to the operation of the occupant using the sensor. The sensed gesture may include the operation of various equipment in the automobile. For example, the above-described sensor detects an operation of an air conditioning facility, a navigation device, an audio/visual (AV) device, a lighting device, or the like. The life log includes a life log of all the occupants. For example, the life log includes an action record of each occupant in the vehicle. By acquiring and storing the life log, it is possible to confirm the state of the occupant at the time of the accident. The health related information detects the body temperature of the occupant using the temperature sensor, and estimates the health condition of the occupant on the basis of the detected body temperature. Alternatively, the face of the occupant may be imaged using an image sensor, and the health condition of the occupant may be estimated from the imaged facial expression. Furthermore, a conversation may be made with the occupant in an automatic voice, and the health condition of the occupant may be estimated on the basis of the answer content of the occupant. The authentication/identification related information includes a keyless entry function of performing face authentication using a sensor, an automatic adjustment function of a seat height and a position in face identification, and the like. The entertainment related information includes a function of detecting operation information of the AV device by the occupant using the sensor, a function of recognizing the face of the occupant by the sensor and providing content suitable for the occupant by the AV device, and the like.

The console display 912 can be used to display the life log information, for example. The console display 912 is disposed near a shift lever 908 of the center console 907 between the driver's seat 901 and the passenger seat 902. The console display 912 can also display information sensed by various sensors (not illustrated). In addition, the console display 912 may display an image of the periphery of the vehicle captured by the image sensor, or may display a distance image to an obstacle in the periphery of the vehicle.

The head-up display 913 is virtually displayed behind a windshield 904 in front of the driver's seat 901. The head-up display 913 can be used to display, for example, at least one of safety related information, operation related information, a life log, health related information, authentication/identification related information, and entertainment related information. Since the head-up display 913 is virtually arranged in front of the driver's seat 901 in many cases, the head-up display 913 is suitable for displaying information directly related to the operation of the automobile such as the speed of the automobile and the remaining amount of fuel (battery).

The digital rear mirror 914 can display not only the rear of the automobile but also the state of the occupant in the back seat, and thus can be used to display the life log information, for example, by disposing a sensor (not illustrated) to overlap the back surface side of the digital rear mirror 914.

The steering wheel display 915 is arranged near the center of a steering wheel 906 of the automobile. The steering wheel display 915 can be used to display, for example, at least one of safety related information, operation related information, a life log, health related information, authentication/identification related information, and entertainment related information. In particular, since the steering wheel display 915 is close to the driver's hand, it is suitable for displaying life log information such as the body temperature of the driver, or for displaying information regarding the operation of an AV device, an air conditioning facility, or the like. The rear entertainment display 916 is attached to the back side of the driver's seat 901 and the passenger seat 902, and is for viewing by an occupant in the back seat. The rear entertainment display 916 can be used to display, for example, at least one of safety related information, operation related information, a life log, health related information, authentication/identification related information, and entertainment related information. In particular, since the rear entertainment display 916 is in front of the occupant in the back seat, information related to the occupant in the back seat is displayed. For example, information regarding the operation of the AV device or the air conditioning facility may be displayed, or a result of measuring the body temperature or the like of the occupant in the back seat by a temperature sensor (not illustrated) may be displayed.

### 13. Supplement

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive combinations of various embodiments, various changes, or modifications within the scope of the technical idea described in the claims, and it is naturally understood that these also belong to the technical scope of the present disclosure.

Furthermore, the effects described in the present specification are merely illustrative or exemplary, and are not restrictive. That is, the technology according to the present disclosure can exhibit other effects obvious to those skilled in the art from the description of the present specification together with or instead of the above effects.

Note that the present technology can also have the following configurations.

(1) A light emitting device comprising a plurality of pixels arranged on a substrate,
wherein a pixel of the plurality of pixels includes a plurality of subpixels,
at least one subpixel of the plurality of subpixels includes a plurality of light emitting elements,
each light emitting element includes:
a first electrode provided on the substrate;
a light emitting layer that is laminated on the first electrode and emits light;
a second electrode that is laminated on the light emitting layer and transmits light from the light emitting layer; and
a first protective film that is laminated on the second electrode and transmits light from the light emitting layer, and
a second protective film constituting an interface for guiding the light immediately above the light emitting element is embedded between the light emitting elements adjacent.
   (2) The light emitting device according to (1),
wherein the second protective film has a refractive index lower than that of the first protective film, and forms an interface for guiding the light immediately above the light emitting element together with the first protective film.
   (3) The light emitting device according to (2), wherein the second protective film is provided to be embedded between the light emitting elements adjacent from a position of an upper surface of the first protective film to a position of a lower surface of the light emitting layer.
   (4) The light emitting device according to any one of (1) to (3), wherein the first protective film includes a nitride film, a transparent conductive film, or a transparent organic film.
   (5) The light emitting device according to any one of (1) to (4), wherein the second protective film includes an oxide film, a resin film, or an air gap.
   (6) The light emitting device according to any one of (1) to (5), wherein the second protective film is provided to cover the first protective film.
   (7) The light emitting device according to (1), further comprising
a third protective film covering the first protective film and the second protective film,
wherein the second protective film has a refractive index lower than those of the first protective film and the third protective film, and forms an interface for guiding the light immediately above the light emitting element together with the third protective film.
   (8) The light emitting device according to (7), wherein the second protective film is made of a metal film.
   (9) The light emitting device according to (7), wherein the third protective film has a refractive index same as or lower than that of the first protective film.
   (10) The light emitting device according to any one of (7) to (9), wherein an upper surface of the second protective film is higher than a position of an upper surface of the first protective film, and a lower surface of the second protective film is lower than a position of an upper surface of the light emitting layer.
   (11) The light emitting device according to any one of (1) to (10),
wherein each light emitting element has a rectangular shape in a case of being viewed from above the substrate, and
a length of one side of the light emitting element is 400 to 800 nm.
   (12) The light emitting device according to any one of (1) to (10),
wherein each light emitting element has a circular shape or an elliptical shape in a case of being viewed from above the substrate.
   (13) The light emitting device according to any one of (1) to (12), wherein all the subpixels of the plurality of subpixels included in the pixel include the plurality of light emitting elements.
   (14) The light emitting device according to any one of (1) to (13), wherein the subpixel includes the plurality of light emitting elements that emits light of a same color.
   (15) The light emitting device according to any one of (1) to (14), wherein the pixel includes the plurality of subpixels that emits light of a same color.
   (16) The light emitting device according to any one of (1) to (14), wherein the pixel includes the plurality of subpixels that emits light of different colors.
   (17) The light emitting device according to (16),
wherein the pixel includes the subpixel that emits green light, the subpixel that emits blue light, and the subpixel that emits red light, and
a width of the light emitting element in the subpixel that emits the green light is narrower than a width of the light emitting element in the subpixel that emits the blue light, and is wider than a width of the light emitting element in the subpixel that emits the red light.
   (18) The light emitting device according to any one of (1) to (17), wherein in the one subpixel, the plurality of light emitting elements shares one on-chip lens laminated above the first protective film.
   (19) The light emitting device according to (18), wherein in the one subpixel, the plurality of light emitting elements shares one color filter laminated above the first protective film.
   (20) The light emitting device according to (19), wherein the plurality of light emitting elements includes the light emitting layer that emits white light.
   (21) The light emitting device according to any one of (1) to (18), wherein the light emitting element includes the light emitting layer that emits one of red light, green light, and blue light.
   (22) The light emitting device according to any one of (1) to (21), wherein in the one subpixel, each first electrode of the light emitting element is electrically connected to each other.
   (23) The light emitting device according to (22), wherein in the one subpixel, the first electrode includes one common electrode shared by the plurality of light emitting elements.
   (24) The light emitting device according to (23),
wherein an upper surface of the common electrode has a first region in which the light emitting layer is laminated and a second region in which the light emitting layer is not laminated,
there is a step between the first region and the second region such that the first region becomes a protrusion, and
the second protective film is provided to be embedded from a position of an upper surface of the first protective film to a position lower than a lower surface of the light emitting layer between the light emitting elements adjacent.
   (25) The light emitting device according to any one of (1) to (24), wherein the first electrode is made of a metal film or a transparent conductive film.
   (26) The light emitting device according to any one of (1) to (25), wherein the second electrode is made of a metal film or a transparent conductive film.
   (27) The light emitting device according to any one of (1) to (26), wherein in the one subpixel, the plurality of light emitting elements is provided to cover the first protective film and shares a common contact electrode electrically connecting the second electrode.
   (28) The light emitting device according to (27), wherein the common contact electrode is electrically connected to a part of a side surface of the second electrode.
   (29) The light emitting device according to (28),
wherein the first protective film has an opening exposing an upper surface of the second electrode, and
the common contact electrode is provided to cover an inner side of the opening.
   (30) An electronic device on which a light emitting device including a plurality of pixels arranged on a substrate is mounted,
wherein a pixel of the plurality of pixels includes a plurality of subpixels,
   at least one subpixel of the plurality of subpixels includes a plurality of light emitting elements,
   each light emitting element includes:
   a first electrode provided on the substrate;
   a light emitting layer that is laminated on the first electrode and emits light;
   a second electrode that is laminated on the light emitting layer and transmits light from the light emitting layer; and
   a first protective film that is laminated on the second electrode and transmits light from the light emitting layer, and
   a second protective film constituting an interface for guiding the light immediately above the light emitting element is embedded between the light emitting elements adjacent.

### REFERENCE SIGNS LIST

10, 10a LIGHT EMITTING DEVICE
11 HORIZONTAL DRIVE CIRCUIT
12 VERTICAL DRIVE CIRCUIT
20, 20a PIXEL
100, 100B, 100B-1, 100B-2, 100G, 100R, 102, 102B,
102G, 102R SUBPIXEL
200, 200a, 200b LIGHT EMITTING ELEMENT
202, 202B, 202G, 202R ANODE ELECTRODE
202a CONNECTION ELECTRODE
204, 204a LIGHT EMITTING LAYER
206 CATHODE ELECTRODE
206a WALL
208, 210, 212, 214 PROTECTIVE FILM
208a OPENING
300 SUBSTRATE
302 COLOR FILTER
304 ON-CHIP LENS
310 COMMON CONTACT ELECTRODE
400 MASK
401, 401B, 401G, 401R REFLECTOR
402, 402B, 402G, 402R OPTICAL ADJUSTMENT LAYER
404, 404B, 404G, 404R. OXIDE FILM
500 DIGITAL STILL CAMERA
511 CAMERA MAIN BODY PORTION
512 IMAGING LENS UNIT
513 GRIP PORTION
514 MONITOR
515 ELECTRONIC VIEW FINDER
600 HEAD MOUNTED DISPLAY
611, 802 DISPLAY UNIT
612 EAR HOOKING PORTION
630 GLASSES
631 LENS BARREL
632 MAIN BODY PORTION
633 ARM
634 SEE-THROUGH HEAD MOUNTED DISPLAY
710 TELEVISION APPARATUS
711 VIDEO DISPLAY SCREEN UNIT
712 FRONT PANEL
713 FILTER GLASS
800 SMARTPHONE
901 DRIVER'S SEAT
902 PASSENGER SEAT
904 WINDSHIELD
906 STEERING WHEEL
907 CENTER CONSOLE
908 SHIFT LEVER
911 CENTER DISPLAY
912 CONSOLE DISPLAY
913 HEAD-UP DISPLAY
914 DIGITAL REAR MIRROR
915 STEERING WHEEL DISPLAY
916 REAR ENTERTAINMENT DISPLAY
C₁ CAPACITOR
C_{EL} CAPACITANCE
DTLₙ SIGNAL LINE
ELP LIGHT EMITTING ELEMENT
PS1ₘ FEEDER LINE
PS2 COMMON FEEDER LINE
SCLₘ SCANNING LINE
TR_{W} WRITE TRANSISTOR
TR_{D} DRIVE TRANSISTOR

1. A light emitting device comprising a plurality of pixels arranged on a substrate,
wherein a pixel of the plurality of pixels includes a plurality of subpixels,
at least one subpixel of the plurality of subpixels includes a plurality of light emitting elements,
each light emitting element includes:
a first electrode provided on the substrate;
a light emitting layer that is laminated on the first electrode and emits light;
a second electrode that is laminated on the light emitting layer and transmits light from the light emitting layer; and
a first protective film that is laminated on the second electrode and transmits light from the light emitting layer, and
a second protective film constituting an interface for guiding the light immediately above the light emitting element is embedded between the light emitting elements adjacent.

2. The light emitting device according to claim 1,
wherein the second protective film has a refractive index lower than that of the first protective film, and forms an interface for guiding the light immediately above the light emitting element together with the first protective film.

3. The light emitting device according to claim 2, wherein the second protective film is provided to be embedded between the light emitting elements adjacent from a position of an upper surface of the first protective film to a position of a lower surface of the light emitting layer.

4. The light emitting device according to claim 1, wherein the first protective film includes a nitride film, a transparent conductive film, or a transparent organic film.

5. The light emitting device according to claim 1, wherein the second protective film includes an oxide film, a resin film, or an air gap.

6. The light emitting device according to claim 1, wherein the second protective film is provided to cover the first protective film.

7. The light emitting device according to claim 1, further comprising
a third protective film covering the first protective film and the second protective film,
wherein the second protective film has a refractive index lower than those of the first protective film and the third protective film, and forms an interface for guiding the light immediately above the light emitting element together with the third protective film.

8. The light emitting device according to claim 7, wherein the second protective film is made of a metal film.

9. The light emitting device according to claim 8, wherein the third protective film has a refractive index same as or lower than that of the first protective film.

10. The light emitting device according to claim 7, wherein an upper surface of the second protective film is higher than a position of an upper surface of the first protective film, and a lower surface of the second protective film is lower than a position of an upper surface of the light emitting layer.

11. The light emitting device according to claim 1,
wherein each light emitting element has a rectangular shape in a case of being viewed from above the substrate, and
a length of one side of the light emitting element is 400 to 800 nm.

12. The light emitting device according to claim 1,
wherein each light emitting element has a circular shape or an elliptical shape in a case of being viewed from above the substrate.

13. The light emitting device according to claim 1, wherein all the subpixels of the plurality of subpixels included in the pixel include the plurality of light emitting elements.

14. The light emitting device according to claim 1, wherein the subpixel includes the plurality of light emitting elements that emits light of a same color.

15. The light emitting device according to claim 1, wherein the pixel includes the plurality of subpixels that emits light of a same color.

16. The light emitting device according to claim 1, wherein the pixel includes the plurality of subpixels that emits light of different colors.

17. The light emitting device according to claim 16,
wherein the pixel includes the subpixel that emits green light, the subpixel that emits blue light, and the subpixel that emits red light, and
a width of the light emitting element in the subpixel that emits the green light is narrower than a width of the light emitting element in the subpixel that emits the blue light, and is wider than a width of the light emitting element in the subpixel that emits the red light.

18. The light emitting device according to claim 1, wherein in the one subpixel, the plurality of light emitting elements shares one on-chip lens laminated above the first protective film.

19. The light emitting device according to claim 18, wherein in the one subpixel, the plurality of light emitting elements shares one color filter laminated above the first protective film.

20. The light emitting device according to claim 19, wherein the plurality of light emitting elements includes the light emitting layer that emits white light.

21. The light emitting device according to claim 1, wherein the light emitting element includes the light emitting layer that emits one of red light, green light, and blue light.

22. The light emitting device according to claim 1,
wherein in the one subpixel,
each first electrode of the light emitting element is electrically connected to each other.

23. The light emitting device according to claim 22, wherein in the one subpixel, the first electrode includes one common electrode shared by the plurality of light emitting elements.

24. The light emitting device according to claim 23,
wherein an upper surface of the common electrode has a first region in which the light emitting layer is laminated and a second region in which the light emitting layer is not laminated,
there is a step between the first region and the second region such that the first region becomes a protrusion, and
the second protective film is provided to be embedded from a position of an upper surface of the first protective film to a position lower than a lower surface of the light emitting layer between the light emitting elements adjacent.

25. The light emitting device according to claim 1, wherein the first electrode is made of a metal film or a transparent conductive film.

26. The light emitting device according to claim 1, wherein the second electrode is made of a metal film or a transparent conductive film.

27. The light emitting device according to claim 1, wherein in the one subpixel, the plurality of light emitting elements is provided to cover the first protective film and shares a common contact electrode electrically connecting the second electrode.

28. The light emitting device according to claim 27, wherein the common contact electrode is electrically connected to a part of a side surface of the second electrode.

29. The light emitting device according to claim 28,
wherein the first protective film has an opening exposing an upper surface of the second electrode, and
the common contact electrode is provided to cover an inner side of the opening.

30. An electronic device on which a light emitting device including a plurality of pixels arranged on a substrate is mounted,
wherein a pixel of the plurality of pixels includes a plurality of subpixels,
at least one subpixel of the plurality of subpixels includes a plurality of light emitting elements,
each light emitting element includes:
a first electrode provided on the substrate;
a light emitting layer that is laminated on the first electrode and emits light;
a second electrode that is laminated on the light emitting layer and transmits light from the light emitting layer; and
a first protective film that is laminated on the second electrode and transmits light from the light emitting layer, and
a second protective film constituting an interface for guiding the light immediately above the light emitting element is embedded between the light emitting elements adjacent.
